(19) United States
(12) Patent Application Publication
(10) Pub. No.: US 2024/0237377 A1
(43) Pub. Date: Jul. 11, 2024

(54) ORGANIC LIGHT EMITTING DIODE AND ORGANIC LIGHT EMITTING DISPLAY DEVICE INCLUDING THE SAME

(71) Applicant: LG Display Co., Ltd., Seoul (KR)

(72) Inventors: Hye-Li Min, Paju-si (KR); In-Ae Shin, Paju-si (KR); Jun-Yun Kim, Paju-shi (KR)

(21) Appl. No.: 18/463,973

(22) Filed: Sep. 8, 2023

(30) Foreign Application Priority Data
Dec. 22, 2022 (KR) 10-2022-0181358

(51) Int. Cl. H10K 50/11; C09K 11/06; H10K 85/30; H10K 85/60

(52) U.S. Cl. CPC H10K 50/11; C09K 11/06; H10K 85/342; H10K 85/658; C09K 2211/1022

(57) ABSTRACT

An organic light emitting diode and an organic light emitting display device including the same includes an anode, a cathode facing the anode, a first emitting part including a first emitting material layer and positioned between the anode and the cathode, and a second emitting part including a second emitting material layer and positioned between the anode and the first emitting part or between the cathode and the first emitting part, wherein the first emitting material layer includes a first emitting layer including a first fluorescent compound being a boron derivative and a second emitting layer including a second fluorescent compound being a boron derivative and positioned between the first emitting layer and the cathode, wherein the second emitting material layer includes a phosphorescent compound.

### CROSS-REFERENCE TO RELATED APPLICATIONS

The present application claims the benefit of Republic of Korea Patent Application No. 10-2022-0181358 filed in the Republic of Korea on Dec. 22, 2022, which is hereby incorporated by reference in its entirety.

### BACKGROUND

### Technical Field

The present disclosure relates to an organic light emitting diode, and more particularly, to an organic light emitting diode having high display performance and an organic light emitting display device including the organic light emitting diode.

### Discussion of the Related Art

Requirement for flat panel display devices having small occupied area is increased. Among the flat panel display devices, a technology of an organic light emitting display device, which includes an organic light emitting diode (OLED) and may be called to as an organic electroluminescent device, is rapidly developed.

The OLED emits light by injecting electrons from a cathode as an electron injection electrode and holes from an anode as a hole injection electrode into an emitting material layer, combining the electrons with the holes, generating an exciton, and transforming the exciton from an excited state to a ground state.

A fluorescent material may be used as an emitter in the OLED. However, since only singlet exciton of the fluorescent material is involved in the emission such that there is a limitation in the emitting efficiency of the fluorescent material.

### SUMMARY

Accordingly, embodiments of the present disclosure are directed to an OLED and an organic light emitting display device that substantially obviate one or more of the problems associated with the limitations and disadvantages of the related art.

An object of the present disclosure is to provide an OLED and an organic light emitting display device having high display performance.

Additional features and aspects will be set forth in the description that follows, and in part will be apparent from the description, or may be learned by practice of the present disclosure concepts provided herein. Other features and aspects of the present disclosure concepts may be realized and attained by the structure particularly pointed out in the written description, or derivable therefrom, and the claims hereof as well as the appended drawings.

To achieve these and other advantages in accordance with the purpose of the embodiments of the present disclosure, as described herein, an aspect of the present disclosure is an organic light emitting diode including an anode; a cathode facing the anode, a first emitting part including a first emitting material layer and positioned between the anode and the cathode, and a second emitting part including a second emitting material layer and positioned between the anode and the first emitting part or between the cathode and the first emitting part, wherein the first emitting material layer includes a first emitting layer including a first fluorescent compound being a boron derivative and a second emitting layer including a second fluorescent compound being a boron derivative and positioned between the first emitting layer and the cathode, wherein the second emitting material layer includes a phosphorescent compound, wherein the first fluorescent compound has a first HOMO energy level and a first LUMO energy level, and wherein the second fluorescent compound has a second HOMO energy level being higher than the first HOMO energy level and a second LUMO energy level being higher than the first LUMO energy level.

Another aspect of the present disclosure is an organic light emitting diode including an anode, a cathode facing the anode, a first emitting part including a first emitting material layer and positioned between the anode and the cathode; and a second emitting part including a second emitting material layer and positioned between the anode and the first emitting part or between the cathode and the first emitting part, wherein the first emitting material layer includes a first emitting layer including a first fluorescent compound and a second emitting layer including a second fluorescent compound and positioned between the first emitting layer and the cathode, wherein the second emitting material layer includes a phosphorescent compound, wherein the first fluorescent compound is represented by Formula 1:

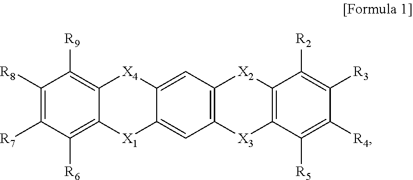

wherein in Formula 1, each of X₁ to X₄ is independently selected from the group consisting of BR₁, NR₁₀, O and S, and each of R₁ to R₁₀ is independently selected from the group consisting of hydrogen, deuterium, a substituted or unsubstituted C1 to C20 alkyl group, a substituted or unsubstituted C3 to C30 cycloalkyl group, a substituted or unsubstituted C6 to C30 aryl group and a substituted or unsubstituted C3 to C30 heteroaryl group, and optionally, at least one of a pair of adjacent two of one of R₁ and R₁₀ and one of R₂, R₅, R₆ and R₉ and a pair of adjacent two of R₂ to R₉ is combined to form a substituted or unsubstituted C4 to C20 alicyclic ring, a substituted or unsubstituted C3 to C20 hetero-alicyclic ring, a substituted or unsubstituted C6 to C30 aromatic ring or a substituted or unsubstituted C3 to C30 heteroaromatic ring, and wherein the second fluorescent compound is represented by Formula 3:

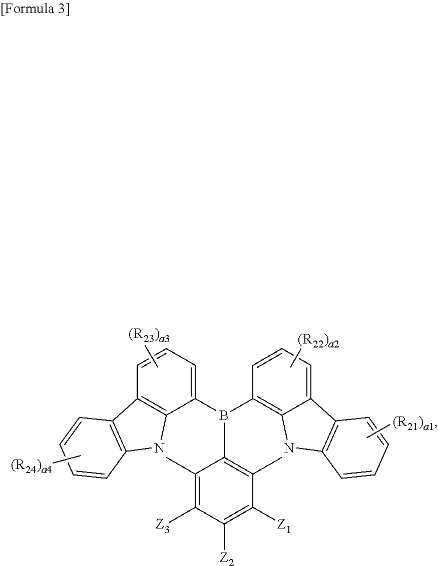

wherein in Formula 3, each of a1 and a4 is independently an integer of 0 to 4, and each of a2 and a3 is independently an integer of 0 to 3, each of R₂₁ to R₂₄ is independently selected from the group consisting of deuterium, a substituted or unsubstituted C1 to C20 alkyl group, a substituted or unsubstituted C3 to C30 cycloalkyl group, a substituted or unsubstituted C6 to C30 aryl group and a substituted or unsubstituted C3 to C30 heteroaryl group, optionally, at least one of a pair of adjacent two R₂₁, a pair of adjacent two R₂₂, a pair of adjacent two R₂₃, and a pair of adjacent two R₂₄ is combined to form a substituted or unsubstituted C4 to C20 alicyclic ring, a substituted or unsubstituted C3 to C20 hetero-alicyclic ring, a substituted or unsubstituted C6 to C30 aromatic ring or a substituted or unsubstituted C3 to C30 heteroaromatic ring, each of Z₁, Z₂ and Z₃ is independently selected from the group consisting of hydrogen, deuterium, a substituted or unsubstituted C1 to C20 alkyl group, a substituted or unsubstituted C3 to C30 cycloalkyl group, a substituted or unsubstituted C6 to C30 aryl group and a substituted or unsubstituted C3 to C30 heteroaryl group, and optionally, adjacent two of Z₁, Z₂ and Z₃ are combined to form a substituted or unsubstituted C4 to C20 alicyclic ring, a substituted or unsubstituted C3 to C20 hetero-alicyclic ring, a substituted or unsubstituted C6 to C30 aromatic ring or a substituted or unsubstituted C3 to C30 heteroaromatic ring.

Another aspect of the present disclosure is an organic light emitting display device including a substrate, and the above organic light emitting diode disposed on the substrate.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the present disclosure and are incorporated in and constitute a part of this application, illustrate embodiments of the present disclosure and together with the description serve to explain principles of the present disclosure.

FIG. 1 is a schematic circuit diagram of an organic light emitting display device of the present disclosure.

FIG. 2 is a schematic cross-sectional view of an organic light emitting display device according to a first embodiment of the present disclosure.

FIG. 3 is a schematic cross-sectional view of an OLED according to a second embodiment of the present disclosure.

FIG. 4 is a schematic cross-sectional view of an OLED according to a third embodiment of the present disclosure.

FIG. 5 is a schematic cross-sectional view of an organic light emitting display device according to a fourth embodiment of the present disclosure.

### DETAILED DESCRIPTION

Reference will now be made in detail to aspects of the present disclosure, examples of which may be illustrated in the accompanying drawings. In the following description, when a detailed description of well-known functions or configurations related to this document is determined to unnecessarily cloud a gist of the inventive concept, the detailed description thereof will be omitted. The progression of processing steps and/or operations described is an example; however, the sequence of steps and/or operations is not limited to that set forth herein and may be changed as is known in the art, with the exception of steps and/or operations necessarily occurring in a particular order. Like reference numerals designate like elements throughout. Names of the respective elements used in the following explanations are selected only for convenience of writing the specification and may be thus different from those used in actual products.

Advantages and features of the present disclosure and methods of achieving them will be apparent with reference to the aspects described below in detail with the accompanying drawings. However, the present disclosure is not limited to the aspects disclosed below, but can be realized in a variety of different forms, and only these aspects allow the disclosure of the present disclosure to be complete. The present disclosure is provided to fully inform the scope of the disclosure to the skilled in the art of the present disclosure.

The shapes, sizes, proportions, angles, numbers, and the like disclosed in the drawings for explaining the aspects of the present disclosure are illustrative, and the present disclosure is not limited to the illustrated matters. The same reference numerals refer to the same elements throughout the specification. In addition, in describing the present disclosure, if it is determined that a detailed description of the related known technology unnecessarily obscure the subject matter of the present disclosure, the detailed description thereof can be omitted. When ‘including’, ‘having’, ‘consisting’, and the like are used in this specification, other parts may be added unless ‘only’ is used. When a component is expressed in the singular, cases including the plural are included unless specific statement is described.

In construing an element, the element is construed as including an error or tolerance range although there is no explicit description of such an error or tolerance range.

In describing a position relationship, for example, when a position relation between two parts is described as, for example, “on,” “over,” “under,” and “next,” one or more other parts may be disposed between the two parts unless a more limiting term, such as “just” or “direct(ly)” is used.

In describing a time relationship, for example, when the temporal order is described as, for example, “after,” “subsequent,” “next,” and “before,” a case that is not continuous may be included unless a more limiting term, such as “just,” “immediate(ly),” or “direct(ly)” is used.

It will be understood that, although the terms “first,” “second,” etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

Features of various aspects of the present disclosure may be partially or overall coupled to or combined with each other, and may be variously inter-operated with each other and driven technically as those skilled in the art can sufficiently understand. The aspects of the present disclosure may be carried out independently from each other, or may be carried out together in co-dependent relationship.

Reference will now be made in detail to some of the examples and preferred embodiments, which are illustrated in the accompanying drawings.

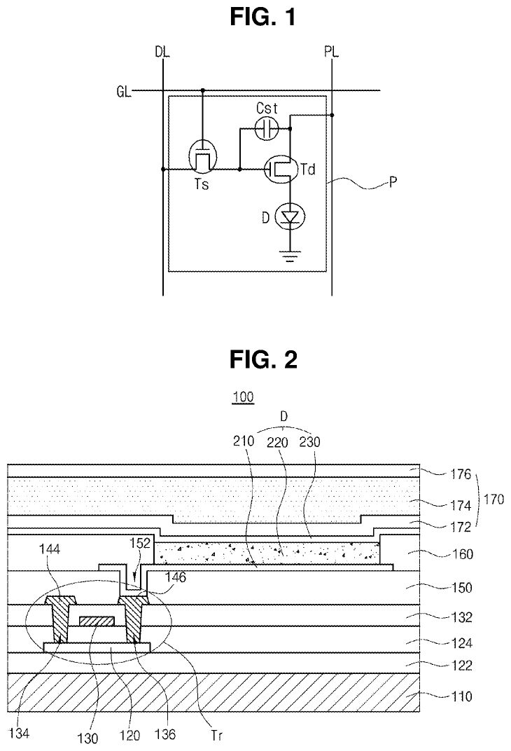

FIG. 1 is a schematic circuit diagram of an organic light emitting display device of the present disclosure.

As shown in FIG. 1, an organic light emitting display device includes a gate line GL, a data line DL, a power line PL, a switching thin film transistor TFT Ts, a driving TFT Td, a storage capacitor Cst, and an OLED D. The gate line GL and the data line DL cross each other to define a pixel region P. The pixel region may include a red pixel region, a green pixel region and a blue pixel region.

The switching TFT Ts is connected to the gate line GL and the data line DL, and the driving TFT Td and the storage capacitor Cst are connected to the switching TFT Ts and the power line PL. The OLED D is connected to the driving TFT Td.

In the organic light emitting display device, when the switching TFT Ts is turned on by a gate signal applied through the gate line GL, a data signal from the data line DL is applied to the gate electrode of the driving TFT Td and an electrode of the storage capacitor Cst.

When the driving TFT Td is turned on by the data signal, an electric current is supplied to the OLED D from the power line PL. As a result, the OLED D emits light. In this case, when the driving TFT Td is turned on, a level of an electric current applied from the power line PL to the OLED D is determined such that the OLED D can produce a gray scale.

The storage capacitor Cst serves to maintain the voltage of the gate electrode of the driving TFT Td when the switching TFT Ts is turned off. Accordingly, even if the switching TFT Ts is turned off, a level of an electric current applied from the power line PL to the OLED D is maintained to next frame.

As a result, the organic light emitting display device displays a desired image.

FIG. 2 is a schematic cross-sectional view of an organic light emitting display device according to a first embodiment of the present disclosure.

As shown in FIG. 2, the organic light emitting display device 100 includes a substrate 110, a TFT Tr on or over the substrate 110, a planarization layer 150 covering the TFT Tr and an OLED D on the planarization layer 150 and connected to the TFT Tr. A red pixel region, a green pixel region and a blue pixel region may be defined on the substrate 110.

The substrate 110 may be a glass substrate or a flexible substrate. For example, the flexible substrate may be one of a polyimide (PI) substrate, a polyethersulfone (PES) substrate, a polyethylenenaphthalate (PEN) substrate, a polyethylene terephthalate (PET) substrate and a polycarbonate (PC) substrate.

A buffer layer 122 is formed on the substrate, and the TFT Tr is formed on the buffer layer 122. The buffer layer 122 may be omitted. For example, the buffer layer 122 may be formed of an inorganic insulating material, e.g., silicon oxide or silicon nitride.

A semiconductor layer 120 is formed on the buffer layer 122. The semiconductor layer 120 may include an oxide semiconductor material or polycrystalline silicon.

When the semiconductor layer 120 includes the oxide semiconductor material, a light-shielding pattern (not shown) may be formed under the semiconductor layer 120. The light to the semiconductor layer 120 is shielded or blocked by the light-shielding pattern such that thermal degradation of the semiconductor layer 120 can be prevented. On the other hand, when the semiconductor layer 120 includes polycrystalline silicon, impurities may be doped into both sides of the semiconductor layer 120.

A gate insulating layer 124 is formed on the semiconductor layer 120. The gate insulating layer 124 may be formed of an inorganic insulating material such as silicon oxide or silicon nitride.

A gate electrode 130, which is formed of a conductive material, e.g., metal, is formed on the gate insulating layer 124 to correspond to a center of the semiconductor layer 120. In FIG. 2, the gate insulating layer 124 is formed on an entire surface of the substrate 110. Alternatively, the gate insulating layer 124 may be patterned to have the same shape as the gate electrode 130.

An interlayer insulating layer 132 is formed on the gate electrode 130 and over an entire surface of the substrate 110. The interlayer insulating layer 132 may be formed of an inorganic insulating material, e.g., silicon oxide or silicon nitride, or an organic insulating material, e.g., benzocyclobutene or photo-acryl.

The interlayer insulating layer 132 includes first and second contact holes 134 and 136 exposing both sides of the semiconductor layer 120. The first and second contact holes 134 and 136 are positioned at both sides of the gate electrode 130 to be spaced apart from the gate electrode 130.

The first contact hole 134 and the second contact hole 136 are formed through the gate insulating layer 124. Alternatively, when the gate insulating layer 124 is patterned to have the same shape as the gate electrode 130, the first and second contact holes 134 and 136 is formed only through the interlayer insulating layer 132.

A source electrode 144 and a drain electrode 146, which are formed of a conductive material, e.g., metal, are formed on the interlayer insulating layer 132.

The source electrode 144 and the drain electrode 146 are spaced apart from each other with respect to the gate electrode 130 and respectively contact both sides of the semiconductor layer 120 through the first and second contact holes 134 and 136.

The semiconductor layer 120, the gate electrode 130, the source electrode 144 and the drain electrode 146 constitute the TFT Tr. The TFT Tr serves as a driving element. Namely, the TFT Tr is the driving TFT Td (of FIG. 1).

In the TFT Tr, the gate electrode 130, the source electrode 144, and the drain electrode 146 are positioned over the semiconductor layer 120. Namely, the TFT Tr has a coplanar structure.

Alternatively, in the TFT Tr, the gate electrode may be positioned under the semiconductor layer, and the source and drain electrodes may be positioned over the semiconductor layer such that the TFT Tr may have an inverted staggered structure. In this instance, the semiconductor layer may include amorphous silicon.

Although not shown, the gate line and the data line cross each other to define the pixel region, and the switching TFT is formed to be connected to the gate and data lines. The switching TFT is connected to the TFT Tr as the driving element. In addition, the power line, which may be formed to be parallel to and spaced apart from one of the gate and data lines, and the storage capacitor for maintaining the voltage of the gate electrode of the TFT Tr in one frame may be further formed.

A planarization layer 150 is formed on an entire surface of the substrate 110 to cover the source and drain electrodes 144 and 146. The planarization layer 150 provides a flat top surface and has a drain contact hole 152 exposing the drain electrode 146 of the TFT Tr.

The OLED D is disposed on the planarization layer 150 and includes a first electrode 210, which is connected to the drain electrode 146 of the TFT Tr, an organic light emitting layer 220 and a second electrode 230. The organic light emitting layer 220 and the second electrode 230 are sequentially stacked on the first electrode 210. The OLED D is positioned in each of the red, green and blue pixel regions and respectively emits the red, green and blue light.

The first electrode 210 is separately formed in each pixel region. The first electrode 210 may be an anode and may include a transparent conductive oxide material layer, which may be formed of a conductive material, e.g., a transparent conductive oxide (TCO), having a relatively high work function, and a reflection layer. Namely, the first electrode 210 may be a reflective electrode.

Alternatively, the first electrode 210 may have a single-layered structure of the transparent conductive oxide material layer. Namely, the first electrode 210 may be a transparent electrode.

For example, the transparent conductive oxide material layer may be formed of one of indium-tin-oxide (ITO), indium-zinc-oxide (IZO), indium-tin-zinc-oxide (ITZO), tin oxide (SnO), zinc oxide (ZnO), indium-copper-oxide (ICO) and aluminum-zinc-oxide (Al:ZnO, AZO), and the reflection layer may be formed of one of silver (Ag), an alloy of Ag and one of palladium (Pd), copper (Cu), indium (In) and neodymium (Nd), and aluminum-palladium-copper (APC) alloy. For example, the first electrode 210 may have a structure of ITO/Ag/ITO or ITO/APC/ITO.

In addition, a bank layer 160 is formed on the planarization layer 150 to cover an edge of the first electrode 210. Namely, the bank layer 160 is positioned at a boundary of the pixel region and exposes a center of the first electrode 210 in the pixel region.

The organic light emitting layer 220 as an emitting unit is formed on the first electrode 210. In the OLED D in the green pixel region, the organic light emitting layer 220 include a first emitting part including a first green emitting material layer (EML) and a second emitting part including a second green EML. Namely, the organic light emitting layer 220 has a multi-stack structure such that the OLED D has a tandem structure.

Each of the first and second emitting parts may further include at least one of a hole injection layer (HIL), a hole transporting layer (HTL), an electron blocking layer (EBL), a hole blocking layer (HBL), an electron transporting layer (ETL) and an electron injection layer (EIL) to have a multi-layered structure. In addition, the organic light emitting layer may further include a charge generation layer (CGL) between the first and second emitting parts.

As explained below, in the OLED D in the green pixel region, the first green EML includes a first green emitting layer, which includes a first host, a first delayed fluorescent compound and a first fluorescent compound as a fluorescent dopant (e.g., a fluorescent emitter), and a second green emitting layer, which includes a second host, a second delayed fluorescent compound and a second fluorescent compound as a fluorescent dopant, and a second green EML includes a third host and a phosphorescent compound as a phosphorescent dopant (e.g., a phosphorescent emitter). As a result, the OLED D has an advantage in at least one of the emitting efficiency and the lifespan.

The second electrode 230 is formed over the substrate 110 where the organic light emitting layer 220 is formed. The second electrode 230 covers an entire surface of the display area and may be formed of a conductive material having a relatively low work function to serve as a cathode. For example, the second electrode 230 may be formed of aluminum (Al), magnesium (Mg), calcium (Ca), silver (Ag) or their alloy, e.g., Mg—Ag alloy (MgAg). The second electrode 230 may have a thin profile, e.g., 10 to 30 nm, to be transparent (or semi-transparent).

Although not shown, the OLED D may further include a capping layer on the second electrode 230. The emitting efficiency of the OLED D may be further improved by the capping layer.

An encapsulation layer (or an encapsulation film) 170 is formed on the second electrode 230 to prevent penetration of moisture into the OLED D. The encapsulation layer 170 includes a first inorganic insulating layer 172, an organic insulating layer 174 and a second inorganic insulating layer 176 sequentially stacked, but it is not limited thereto.

In a bottom-emission type organic light emitting display device 100, a metal plate may be disposed on the encapsulation layer 170.

Although not shown, the organic light emitting display device 100 may include a color filter corresponding to the red, green and blue pixel regions. For example, the color filter may be positioned on or over the OLED D or the encapsulation layer 170.

The organic light emitting display device 100 may further include a polarization plate for reducing an ambient light reflection. For example, the polarization plate may be a circular polarization plate. In a bottom-emission type organic light emitting display device 100, the polarization plate may be disposed under the substrate 110. In a top-emission type organic light emitting display device 100, the polarization plate may be disposed on the encapsulation layer 170.

In addition, the organic light emitting display device 100 may further include a cover window (not shown) on or over the encapsulation layer 170 or the color filter. In this instance, the substrate 110 and the cover window have a flexible property such that a flexible organic light emitting display device may be provided.

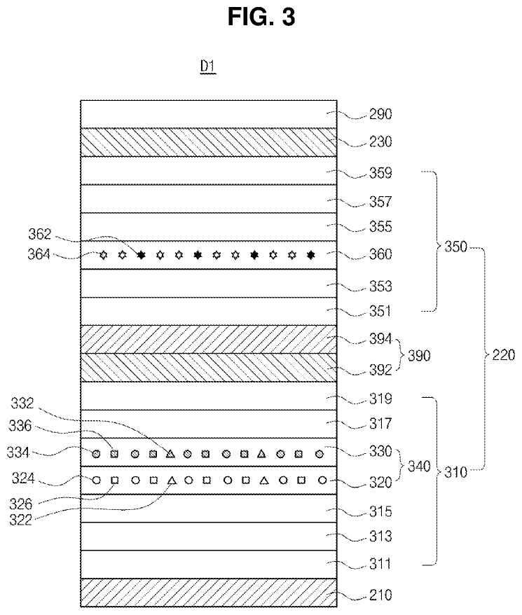

FIG. 3 is a schematic cross-sectional view of an OLED according to a second embodiment of the present disclosure.

As shown in FIG. 3, the OLED D1 includes the first electrode 210 as an anode for injecting a hole, the second electrode 230 as a cathode for injecting an electron facing the first electrode 210, and the organic light emitting layer 220 therebetween. The organic light emitting layer 220 includes a first emitting part 310 (e.g., a first green emitting part) including a first EML 340 (e.g., a first green EML), which has a double-layered structure including a first emitting layer 320 (e.g., a first green emitting layer) and a second emitting layer 330 (e.g., a second green emitting layer), and being disposed to be closer to the first electrode 210, and a second emitting part 350 (e.g., a second green emitting part) including a second EML 360 (e.g., a second green EML), which has a single-layered structure, and being disposed to be closer to the second electrode 230. In addition, the organic light emitting layer 220 may further include a CGL 390 between the first emitting part 310 and the second emitting part 350. Moreover, the OLED D1 may further include a capping layer 290 for enhancing (improving) an emitting efficiency.

The organic light emitting display device may include a red pixel region, a green pixel region and a blue pixel region, and the OLED D1 is positioned in the green pixel region.

One of the first and second electrodes 210 and 230 may be a transparent electrode (e.g., a semitransparent electrode, and the other one of the first and second electrodes 210 and 230 may be a reflective electrode. For example, the first electrode 210 may be formed of ITO, and the second electrode 230 may be formed of MgAg. Each of the first and second electrodes 210 and 230 may have a thickness of 5 to 30 nm.

In the first emitting part 310, the first emitting layer 320 and the second emitting layer 330 contact each other. Namely, the first EML 340 in the first emitting part 310 has a double-layered structure.

The first emitting layer 320 is positioned between the first electrode 210 and the second emitting layer 330. Namely, the first emitting layer 320 is closer to the first electrode 210 as an anode, and the second emitting layer 330 is closer to the second electrode 230 as a cathode.

The first EML 340 may have a thickness of 20 to 60 nm, and each of the first and second emitting layers 320 and 330 may have a thickness of 10 to 50 nm. For example, the first and second emitting layers 320 and 330 may have the same thickness.

The first emitting layer 320 includes a first fluorescent compound 322 and a first delayed fluorescent compound 324. The first emitting layer 320 may further include a first host 326.

In the first emitting layer 320, the first fluorescent compound 322 serves as an emitter (e.g., a dopant), and the first delayed fluorescent compound 324 serves as an auxiliary dopant or an auxiliary host. For example, in the first emitting layer 320, an exciton generated in the first host 326 may be transferred to the first fluorescent compound 322 through the first delayed fluorescent compound 324 so that the emission may be provided from the first fluorescent compound 322.

In the first emitting layer 320, the first fluorescent compound 322 has a first weight %, and each of a second weight % of the first delayed fluorescent compound 324 and a third weight % of the first host 326 is greater than the first weight %. The second weight % of the first delayed fluorescent compound 324 and the third weight % of the first host 326 may be same or different. For example, in the first emitting layer 320, the first delayed fluorescent compound 324 and the first host 326 may have the same weight %, and the first fluorescent compound 322 may have a weight % of 0.1 to 10, preferably 0.2 to 2.0.

The second emitting layer 330 includes a second fluorescent compound 332 and a second delayed fluorescent compound 334. The second emitting layer 330 may further include a second host 336.

In the second emitting layer 330, the second fluorescent compound 332 serves as an emitter (e.g., a dopant), and the second delayed fluorescent compound 334 serves as an auxiliary dopant or an auxiliary host. For example, in the second emitting layer 330, an exciton generated in the second host 336 may be transferred to the second fluorescent compound 332 through the second delayed fluorescent compound 334 so that the emission may be provided from the second fluorescent compound 332.

In the second emitting layer 330, the second fluorescent compound 332 has a fourth weight %, and each of a fifth weight % of the second delayed fluorescent compound 334 and a sixth weight % of the second host 336 is greater than the fourth weight %. The fifth weight % of the second delayed fluorescent compound 334 and the sixth weight % of the first host 336 may be same or different. For example, in the second emitting layer 330, the second delayed fluorescent compound 334 and the second host 336 may have the same weight %, and the second fluorescent compound 332 may have a weight % of 0.1 to 10, preferably 0.2 to 2.0.

The first weight % of the first fluorescent compound 322 in the first emitting layer 320 may be greater than the fourth weight % of the second fluorescent compound 332 in the second emitting layer 330. For example, the first weight % of the first fluorescent compound 322 may be in a range of 0.7 to 2.0, and the fourth weight % of the second fluorescent compound 332 may be in a range of 0.2 to 0.7.

The first fluorescent compound 322 in the first emitting layer 320 is a boron derivative having a first highest occupied molecular orbital (HOMO) energy level and a first lowest unoccupied molecular orbital (LUMO) energy level.

The first fluorescent compound 322 is represented by Formula 1.

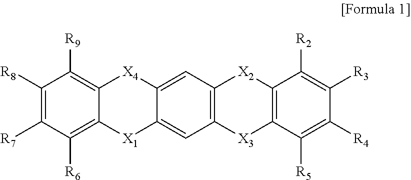

In Formula 1, each of X₁ to X₄ is independently selected from the group consisting of BR₁, NR₁₀, O and S, and

each of R₁ to R₁₀ is independently selected from the group consisting of hydrogen, deuterium, a substituted or unsubstituted C1 to C20 alkyl group, a substituted or unsubstituted C3 to C30 cycloalkyl group, a substituted or unsubstituted C6 to C30 aryl group and a substituted or unsubstituted C3 to C30 heteroaryl group, and
optionally, at least one of a pair of adjacent two of one of R₁ and R₁₀ and one of R₂, R₅, R₆ and R₉ and a pair of adjacent two of R₂ to R₉ is combined to form a substituted or unsubstituted C4 to C20 alicyclic ring, a substituted or unsubstituted C3 to C20 hetero-alicyclic ring, a substituted or unsubstituted C6 to C30 aromatic ring or a substituted or unsubstituted C3 to C30 heteroaromatic ring.

In the present disclosure, without specific definition, a substituent may be at least one of deuterium, halogen, cyano, a C1 to C10 alkyl group and a C6 to C30 aryl group.

In the present disclosure, without specific definition, a C1 to C20 alkyl group may be selected from the group consisting of methyl, ethyl, n-propyl, isopropyl, n-butyl, tert-butyl and isobutyl.

In the present disclosure, the C6 to C30 aryl group (or C6 to C30 aromatic group) may be selected from the group consisting of phenyl, biphenyl, terphenyl, naphthyl, anthracenyl, pentanenyl, indenyl, indenoindenyl, heptalenyl, biphenylenyl, indacenyl, phenanthrenyl, benzophenanthrenyl, dibenzophenanthrenyl, azulenyl, pyrenyl, fluoranthenyl, triphenylenyl, chrysenyl, tetraphenyl, tetrasenyl, picenyl, pentaphenyl, pentacenyl, fluorenyl, indenofluorenyl and spiro-fluorenyl.

In the present disclosure, the C3 to C30 heteroaryl group (C3 to C30 heteroaromatic group) may be selected from the group consisting of pyrrolyl, pyridinyl, pyrimidinyl, pyrazinyl, pyridazinyl, triazinyl, tetrazinyl, imidazolyl, pyrazolyl, indolyl, isoindolyl, indazolyl, indolizinyl, pyrrolizinyl, carbazolyl, benzocarbazolyl, dibenzocarbazolyl, indolocarbazolyl, indenocarbazolyl, benzofurocarbazolyl, benzothienocarbazolyl, quinolinyl, isoquinolinyl, phthalazinyl, quinoxalinyl, cinnolinyl, quinazolinyl, quinozolinyl, purinyl, benzoquinolinyl, benzoisoquinolinyl, benzoquinazolinyl, benzoquinoxalinyl, acridinyl, phenanthrolinyl, perimidinyl, phenanthridinyl, pteridinyl, naphtharidinyl, furanyl, oxazinyl, oxazolyl, oxadiazolyl, triazolyl, dioxynyl, benzofuranyl, dibenzofuranyl, thiopyranyl, xanthenyl, chromanyl, isochromanyl, thioazinyl, thiophenyl, benzothiophenyl, dibenzothiophenyl, difuropyrazinyl, benzofurodibenzofuranyl, benzothienobenzothiophenyl, benzothienodibenzothiophenyl, benzothienobenzofuranyl, and benzothienodibenzofuranyl.

In an aspect of the present disclosure, two of X₁ to X₄ may be BR₁, and the other two of X₁ to X₄ may be NR₁₀ or O.

In an aspect of the present disclosure, Formula 1 may be represented by Formula 1a.

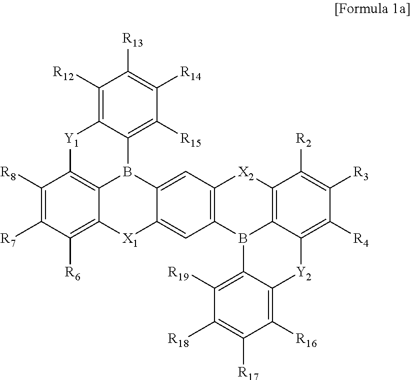

In Formula 1a, each of X₁ and X₂ is independently NR₁₀ or O,
each of Y₁ and Y₂ is independently NR₁₁ or O,
each of R₂ to R₄, R₆ to R₈, R₁₀ to R₁₉ is independently selected from the group consisting of hydrogen, deuterium, a substituted or unsubstituted C1 to C20 alkyl group, a substituted or unsubstituted C3 to C30 cycloalkyl group, a substituted or unsubstituted C6 to C30 aryl group and a substituted or unsubstituted C3 to C30 heteroaryl group, or
optionally, at least one of a pair of adjacent two of Rn and one of R₈ and R₁₂ and a pair of adjacent two of R₁₁ and one of R₄ and R₁₆ is combined to form a substituted or unsubstituted C4 to C20 alicyclic ring, a substituted or unsubstituted C3 to C20 hetero-alicyclic ring, a substituted or unsubstituted C6 to C30 aromatic ring or a substituted or unsubstituted C3 to C30 heteroaromatic ring.

In an aspect of the present disclosure, each of X₁ and X₂ may be O.

In an aspect of the present disclosure, each of X₁ and X₂ may be NR₁₀, and R₁₀ may be a C6 to C30 aryl group, e.g., phenyl, unsubstituted or substituted with at least one C1 to C20 alkyl group, e.g., methyl, isopropyl or tert-butyl.

In an aspect of the present disclosure, each of Y₁ and Y₂ may be O.

In an aspect of the present disclosure, each of Y₁ and Y₂ may be NR₁₁, and Ru may be a C6 to C30 aryl group, e.g., phenyl, unsubstituted or substituted with at least one C1 to C20 alkyl group, e.g., methyl, isopropyl or tert-butyl, or may be combined with one of R₈ and R₁₂ and one of R₄ and R₁₆ to form a substituted or unsubstituted C3 to C30 heteroaromatic ring.

In an aspect of the present disclosure, R₁₁, one of R₈ and R₁₂ and one of R₄ and R₁₆ may be combined to form a substituted or unsubstituted carbazole ring with an adjacent benzene ring.

For example, the first fluorescent compound 322 in the first emitting layer 320 may be one of compounds in Formula 2.

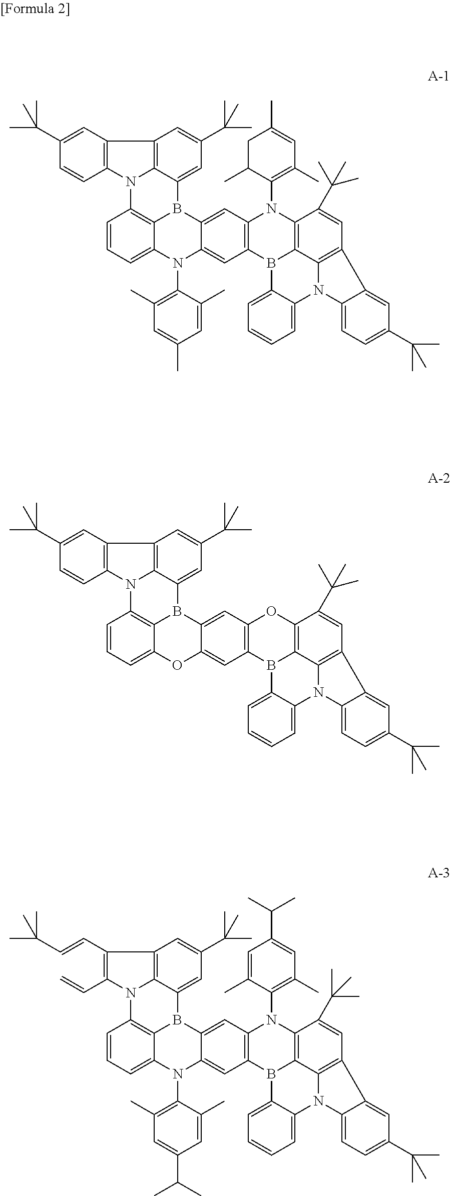

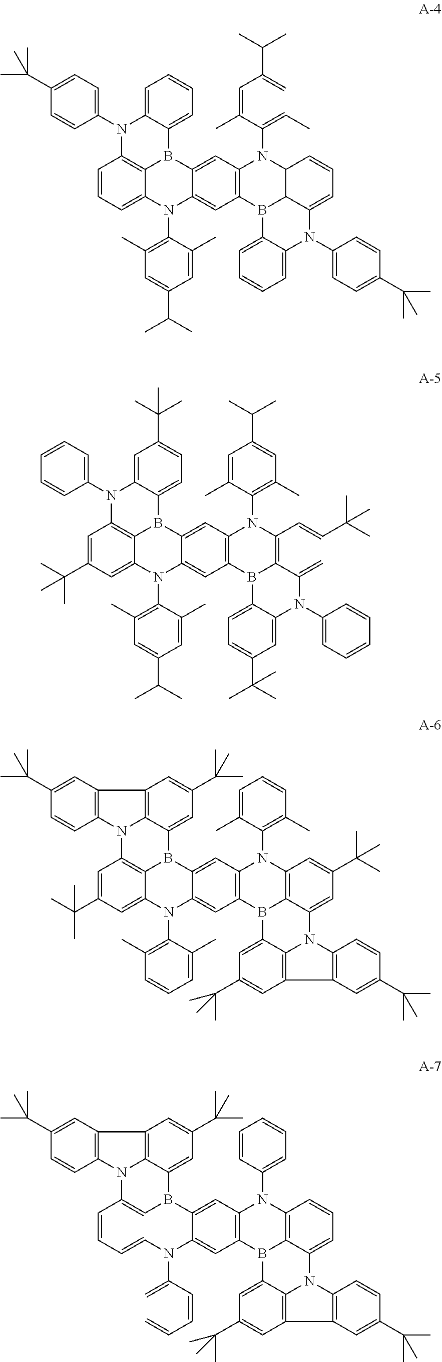

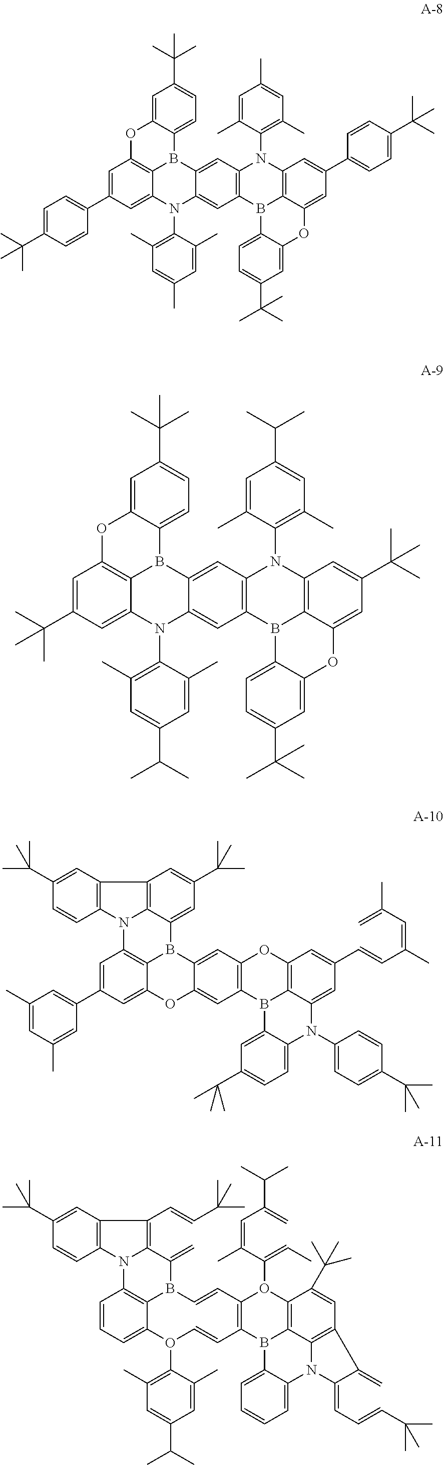

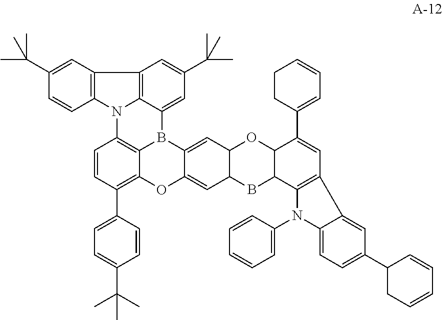

The second fluorescent compound 332 in the second emitting layer 330 is a boron derivative having a second HOMO energy level, which is higher than the first HOMO energy level, and a second LUMO energy level, which is higher than the first LUMO energy level.

The second fluorescent compound 332 is represented by Formula 3.

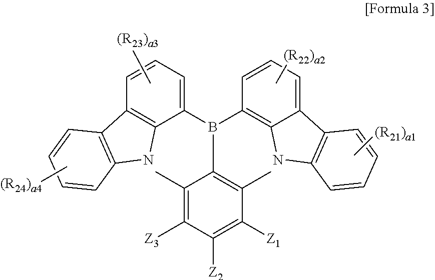

In Formula 3, each of a1 and a4 is independently an integer of 0 to 4, and each of a2 and a3 is independently an integer of 0 to 3,
each of R₂₁ to R₂₄ is independently selected from the group consisting of deuterium, a substituted or unsubstituted C1 to C20 alkyl group, a substituted or unsubstituted C3 to C30 cycloalkyl group, a substituted or unsubstituted C6 to C30 aryl group and a substituted or unsubstituted C3 to C30 heteroaryl group,
optionally, at least one of a pair of adjacent two R₂₁, a pair of adjacent two R₂₂, a pair of adjacent two R₂₃, and a pair of adjacent two R₂₄ is combined to form a substituted or unsubstituted C4 to C20 alicyclic ring, a substituted or unsubstituted C3 to C20 hetero-alicyclic ring, a substituted or unsubstituted C6 to C30 aromatic ring or a substituted or unsubstituted C3 to C30 heteroaromatic ring,
each of Z₁, Z₂ and Z₃ is independently selected from the group consisting of hydrogen, deuterium, a substituted or unsubstituted C1 to C20 alkyl group, a substituted or unsubstituted C3 to C30 cycloalkyl group, a substituted or unsubstituted C6 to C30 aryl group and a substituted or unsubstituted C3 to C30 heteroaryl group, and
optionally, adjacent two of Z₁, Z₂ and Z₃ are combined to form a substituted or unsubstituted C4 to C20 alicyclic ring, a substituted or unsubstituted C3 to C20 hetero-alicyclic ring, a substituted or unsubstituted C6 to C30 aromatic ring or a substituted or unsubstituted C3 to C30 heteroaromatic ring.

In an aspect of the present disclosure, each of a1, a2, a3 and a4 may be 1, and each of R₂₁, R₂₂, R₂₃ and R₂₄ may be independently selected from the group consisting of a substituted or unsubstituted C1 to C20 alkyl group, e.g., tert-butyl, and a substituted or unsubstituted C6 to C30 aryl group, e.g., phenyl.

In an aspect of the present disclosure, adjacent two R₂₃ may be combined to each other with a benzene ring to form a substituted or unsubstituted C3 to C30 heteroaromatic ring, e.g., carbazole.

In an aspect of the present disclosure, one of Z₁, Z₂ and Z₃ may be a substituted or unsubstituted C3 to C30 heteroaryl group, e.g., carbazolyl, and the other two of Z₁, Z₂ and Z₃ may be hydrogen.

In an aspect of the present disclosure, adjacent two of Z₁, Z₂ and Z₃ may be combined to each other with a benzene ring to form a substituted or unsubstituted C3 to C30 heteroaromatic ring.

For example, the second fluorescent compound 332 in the second emitting layer 330 may be one of compounds in Formula 4.

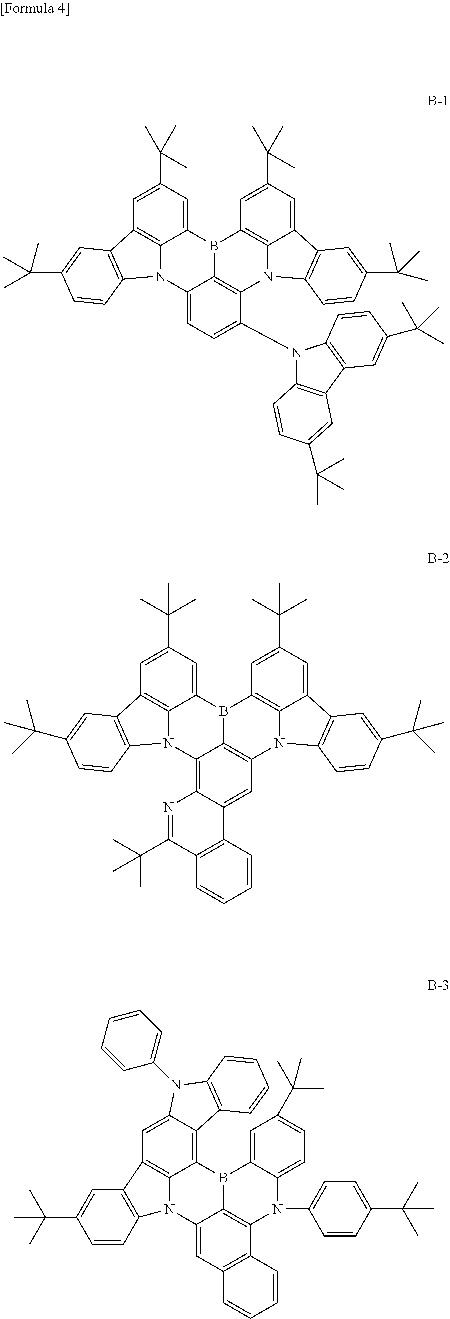

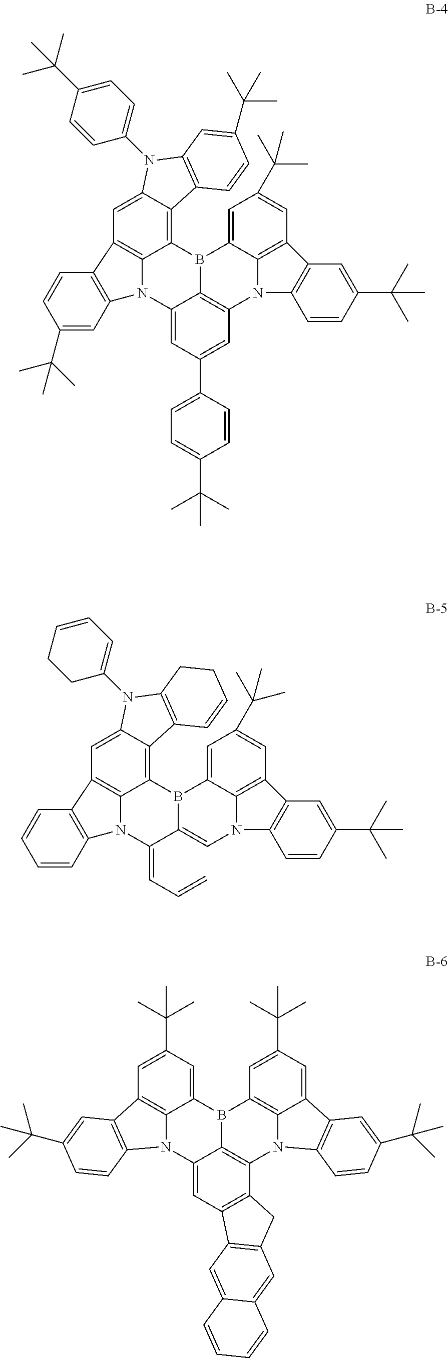

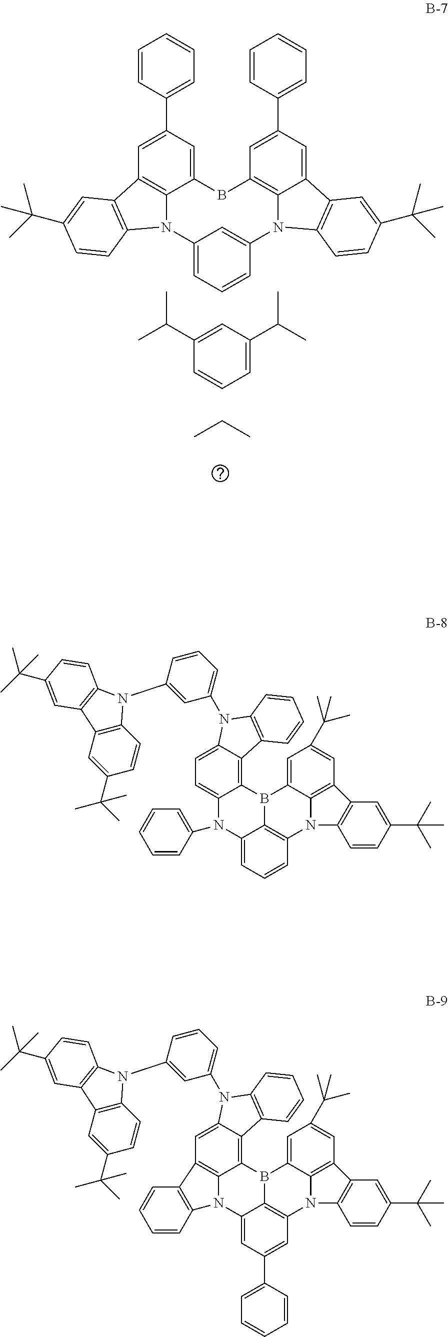

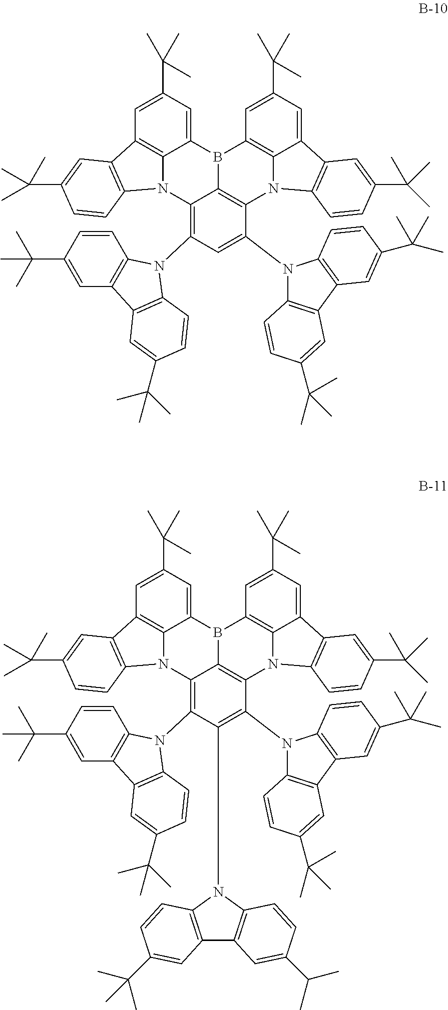

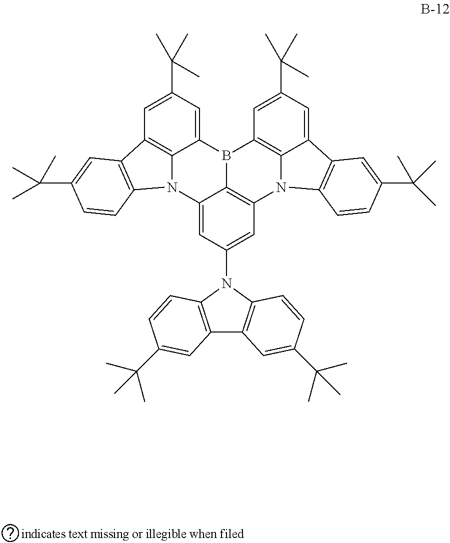 [SMILES: CC(C)(C)c1ccc2c(c1)c1cc(C(C)(C)C)ccc1n2-c1cc2c3c(c1)-n1c4ccc(C(C)(C)C)cc4c4cc(C(C)(C)C)cc(c41)B3c1cc(C(C)(C)C)cc3c4cc(C(C)(C)C)ccc4n-2c13]

Namely, each of the first fluorescent compound 322 in the first emitting layer 320 and the second first fluorescent compound 332 in the second emitting layer 330 is a boron derivative, while the first fluorescent compound 322 and the second first fluorescent compound 332 have a difference in a chemical structure, a HOMO energy level and a LUMO energy level.

Each of the first delayed fluorescent compound 324 in the first emitting layer 320 and the second delayed fluorescent compound 334 in the second emitting layer 330 is independently selected from compounds in Formula 5.

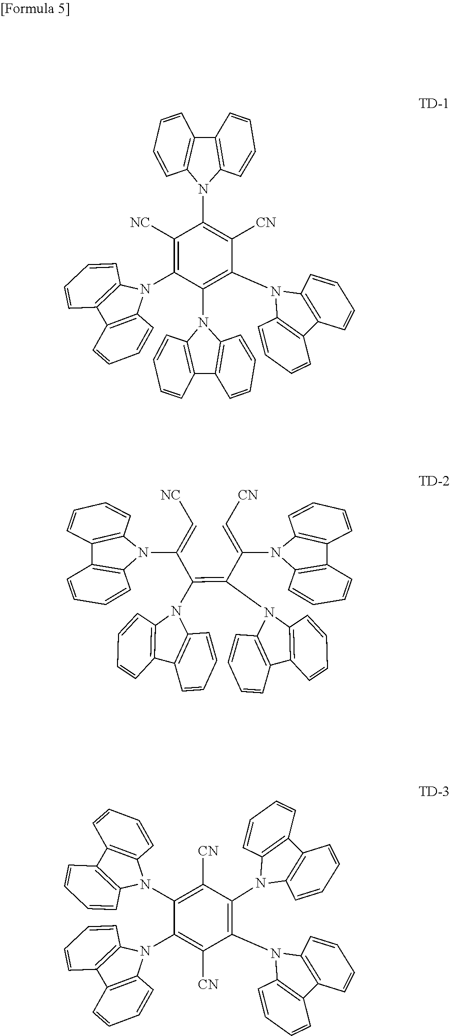 [SMILES: N#Cc1c(-n2c3ccccc3c3ccccc32)c(C#N)c(-n2c3ccccc3c3ccccc32)c(-n2c3ccccc3c3ccccc32)c1-n1c2ccccc2c2ccccc21 ; N#C/C=C(/C(=C(\C(=C\C#N)n1c2ccccc2c2ccccc21)n1c2ccccc2c2ccccc21)n1c2ccccc2c2ccccc21)n1c2ccccc2c2ccccc21 ; N#Cc1c(-n2c3ccccc3c3ccccc32)c(-n2c3ccccc3c3ccccc32)c(C#N)c(-n2c3ccccc3c3ccccc32)c1-n1c2ccccc2c2ccccc21]

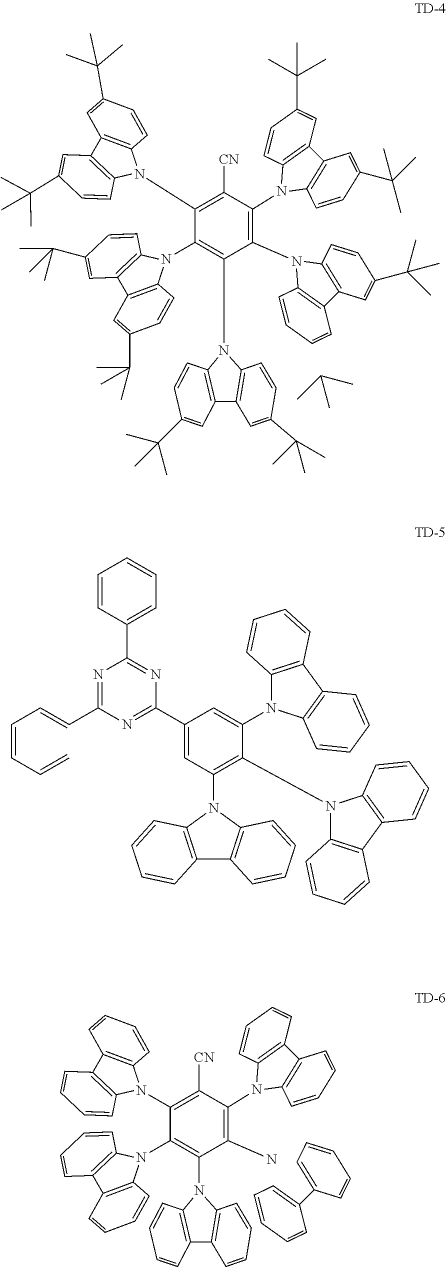

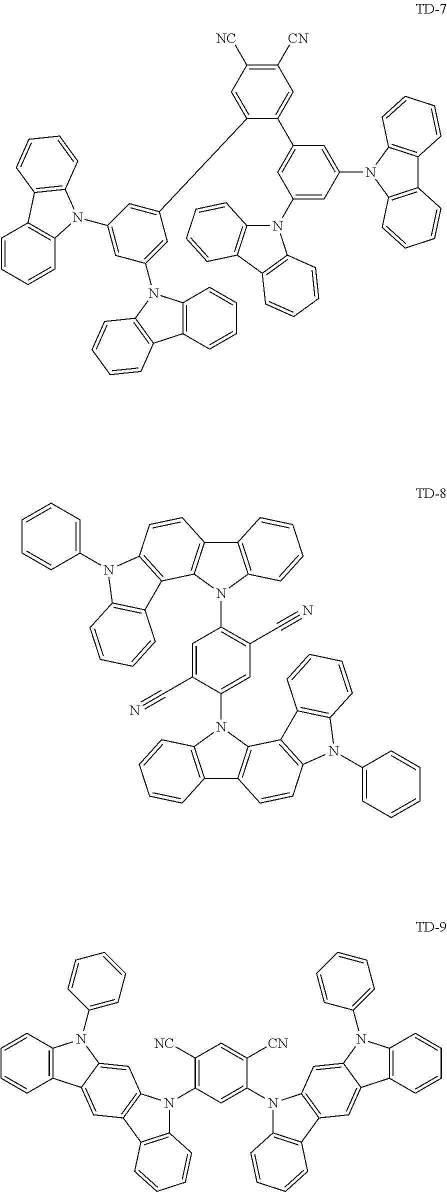 [SMILES: N#Cc1cc(-c2cc(-n3c4ccccc4c4ccccc43)cc(-n3c4ccccc4c4ccccc43)c2)c(-c2cc(-n3c4ccccc4c4ccccc43)cc(-n3c4ccccc4c4ccccc43)c2)cc1C#N ; N#Cc1cc(-n2c3ccccc3c3ccc4c(c5ccccc5n4-c4ccccc4)c32)c(C#N)cc1-n1c2ccccc2c2ccc3c(c4ccccc4n3-c3ccccc3)c21 ; N#Cc1cc(C#N)c(-n2c3ccccc3c3cc4c5ccccc5n(-c5ccccc5)c4cc32)cc1-n1c2ccccc2c2cc3c4ccccc4n(-c4ccccc4)c3cc21]

The first delayed fluorescent compound 324 and the second delayed fluorescent compound 334 may be same or different.

Each of the first host 326 in the first emitting layer 320 and the second host 336 in the second emitting layer 330 is independently selected from compounds in Formula 6.

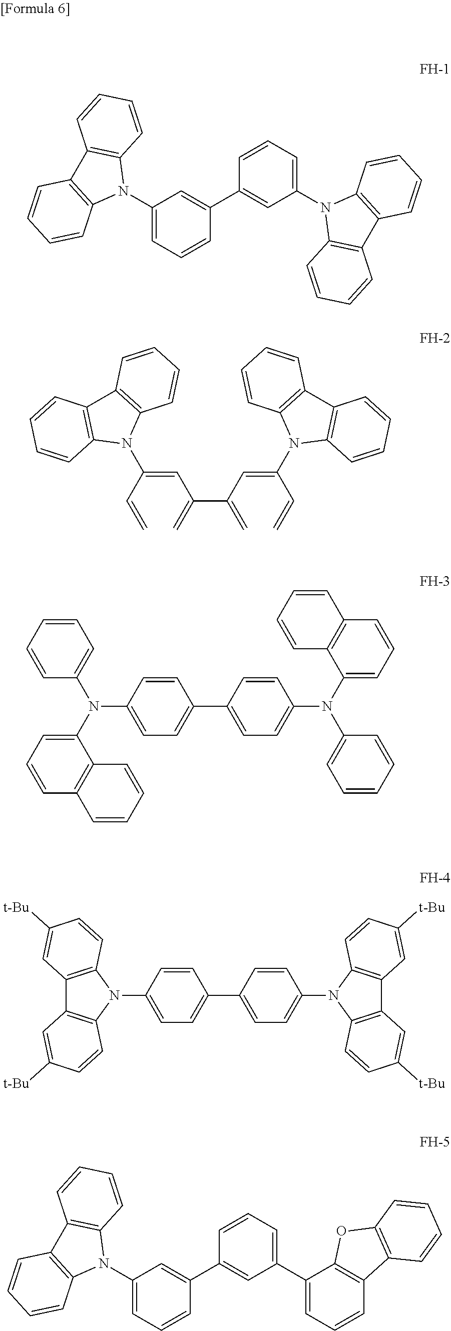 [SMILES: c1cc(-c2cccc(-n3c4ccccc4c4ccccc43)c2)cc(-n2c3ccccc3c3ccccc32)c1 ; C=C/C(=C\C(=C)C(=C)/C=C(\C=C)n1c2ccccc2c2ccccc21)n1c2ccccc2c2ccccc21 ; c1ccc(N(c2ccc(-c3ccc(N(c4ccccc4)c4cccc5ccccc45)cc3)cc2)c2cccc3ccccc23)cc1 ; CC(C)(C)c1ccc2c(c1)c1cc(C(C)(C)C)ccc1n2-c1ccc(-c2ccc(-n3c4ccc(C(C)(C)C)cc4c4cc(C(C)(C)C)ccc43)cc2)cc1 ; c1cc(-c2cccc(-n3c4ccccc4c4ccccc43)c2)cc(-c2cccc3c2oc2ccccc23)c1]

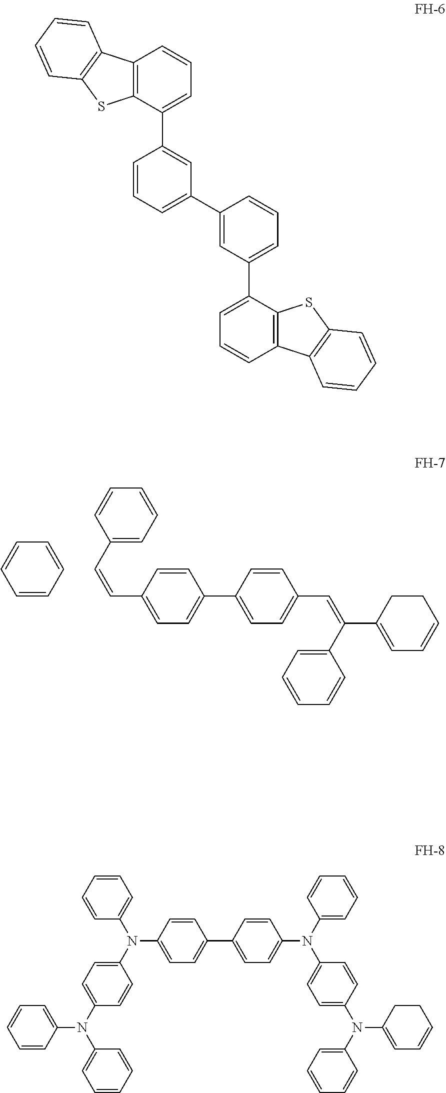

The first host 326 and the second host 336 may be same or different.

In the first emitting layer 320, the first delayed fluorescent compound 324 is selected from the compounds in Formula 5, and the first host 326 is selected from the compounds in Formula 6. As a result, an exciton generation efficiency in the first emitting layer 320 and an energy transfer efficiency into the first fluorescent compound 322 are improved. In addition, in the second emitting layer 330, the second delayed fluorescent compound 334 is selected from the compounds in Formula 5, and the second host 336 is selected from the compounds in Formula 6. As a result, an exciton generation efficiency in the second emitting layer 330 and an energy transfer efficiency into the second fluorescent compound 332 are improved.

The first emitting part 310 may further include at least one of a first HTL 313 positioned under the first EML 340 and a first ETL 319 positioned on the first EML 340.

In addition, the first emitting part 310 may further include an HIL 311 positioned under the first HTL 313.

Moreover, the first emitting part 310 may further include at least one of a first EBL 315 positioned between the first EML 340 and the first HTL 313 and a first HBL 317 positioned between the first EML 340 and the first ETL 319.

In the second emitting part 350, the second EML 360 has a single-layered structure and may have a thickness of 20 to 60 nm.

The second EML 360 includes a phosphorescent compound 362 as a dopant (e.g., an emitter). In addition, the second EML 360 may further include a third host 364.

In the second EML 360, the phosphorescent compound 362 has a seventh weight %, and the third host 364 has an eighth weight % being greater than the seventh weight %. For example, in the second EML 360, the phosphorescent compound 362 may have a weight % of 1 to 5, and the third host 364 may have a weight % of 95 to 99.

The phosphorescent compound 362 in the second EML 360 may be an iridium complex. For example, the phosphorescent compound 362 may be one of compounds in Formula 7.

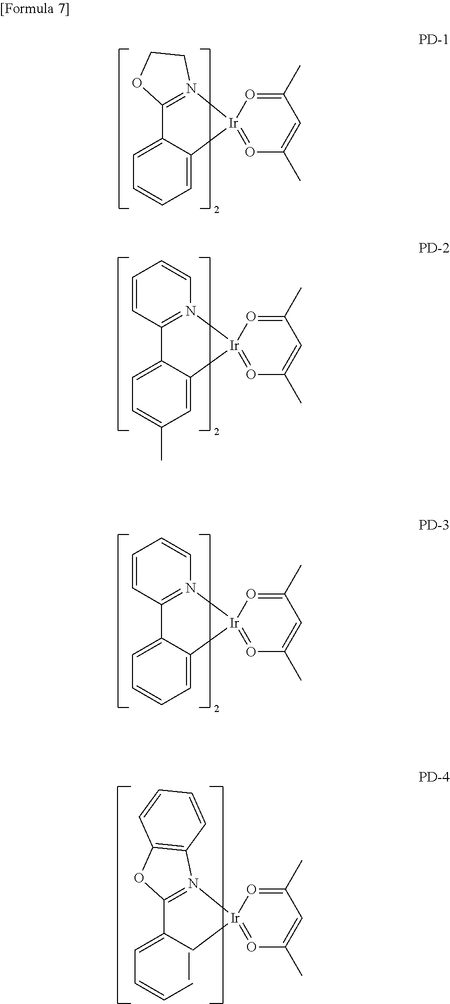

The third host 364 in the second EML 360 may be one of compounds in Formula 8.

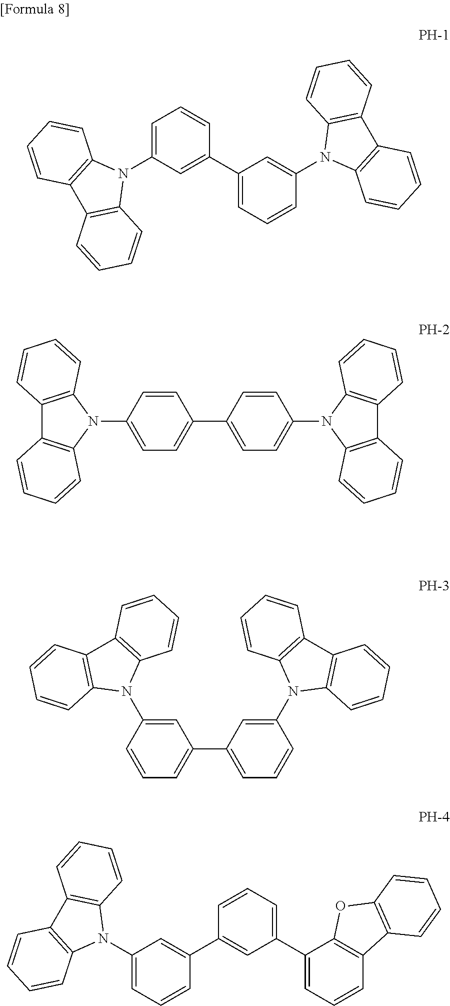 [SMILES: c1cc(-c2cccc(-n3c4ccccc4c4ccccc43)c2)cc(-n2c3ccccc3c3ccccc32)c1 ; c1ccc2c(c1)c1ccccc1n2-c1ccc(-c2ccc(-n3c4ccccc4c4ccccc43)cc2)cc1 ; c1cc(-c2cccc(-n3c4ccccc4c4ccccc43)c2)cc(-n2c3ccccc3c3ccccc32)c1 ; c1cc(-c2cccc(-n3c4ccccc4c4ccccc43)c2)cc(-c2cccc3c2oc2ccccc23)c1]

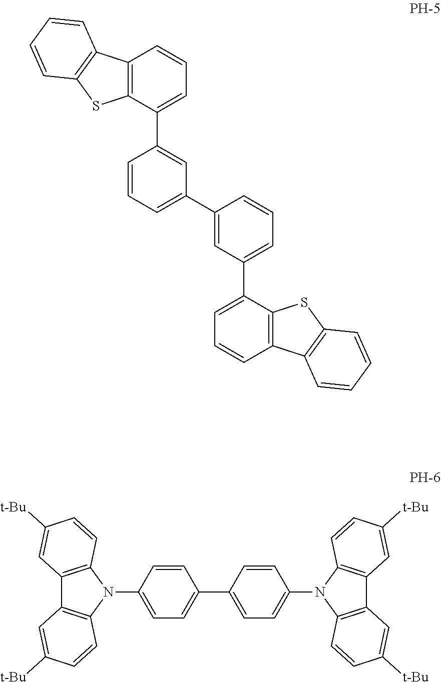 [SMILES: c1cc(-c2cccc(-c3cccc4c3sc3ccccc34)c2)cc(-c2cccc3c2sc2ccccc23)c1 ; CC(C)(C)c1ccc2c(c1)c1cc(C(C)(C)C)ccc1n2-c1ccc(-c2ccc(-n3c4ccc(C(C)(C)C)cc4c4cc(C(C)(C)C)ccc43)cc2)cc1]

The second emitting part 350 may further include at least one of a second HTL 351 positioned under the second EML 360 and a second ETL 357 positioned on the second EML 360.

In addition, the second emitting part 350 may further include an EIL 359 positioned on the second ETL 357.

Moreover, the second emitting part 350 may further include at least one of a second EBL 353 positioned between the second EML 360 and the second HTL 351 and a second HBL 355 positioned between the second EML 360 and the second ETL 357.

For example, the HIL 311 may include a hole injection material being one of 4,4′,4″-tris(3-methylphenylamino)triphenylamine (MTDATA), 4,4′,4″-tris(N,N-diphenyl-amino)triphenylamine (NATA), 4,4′,4″-tris(N-(naphthalene-1-yl)-N-phenyl-amino)triphenylamine (1T-NATA), 4,4′,4″-tris(N-(naphthalene-2-yl)-N-phenyl-amino)triphenylamine (2T-NATA), copper phthalocyanine(CuPc), tris(4-carbazoyl-9-yl-phenyl)amine (TCTA), N,N′-diphenyl-N,N′-bis(1-naphthyl)-1,1′-biphenyl-4,4″-diamine (NPB or NPD), 1,4,5,8,9,11-hexaazatriphenylenehexacarbonitrile (dipyrazino[2,3-f:2′ 3′-h]quinoxaline-2,3,6,7,10,11-hexacarbonitrile (HAT-CN)), 1,3,5-tris[4-(diphenylamino)phenyl]benzene (TDAPB), poly(3,4-ethylenedioxythiphene)polystyrene sulfonate (PEDOT/PSS), N-(biphenyl-4-yl)-9,9-dimethyl-N-(4-(9-phenyl-9H-carbazol-3-yl)phenyl)-9H-fluoren-2-amine, and N,N′-diphenyl-N,N′-di[4-(N,N-diphenyl-amino)phenyl]benzidine (NPNPB), but it is not limited thereto. For example, the hole injection material of the HIL 311 may be a compound in Formula 9. The HIL 311 may have a thickness of 1 to 20 nm.

Each of the first HTL 313 and the second HTL 351 may include a hole transporting material being one of N,N′-diphenyl-N,N′-bis(3-methylphenyl)-1,1′-biphenyl-4,4′-diamine (TPD), NPB (or NPD), 4,4′-bis(N-carbazolyl)-1,1′-biphenyl (CBP), poly[N,N′-bis(4-butylpnehyl)-N,N′-bis(phenyl)-benzidine] (poly-TPD), (poly[(9,9-dioctylfluorenyl-2,7-diyl)-co-(4,4′-(N-(4-sec-butylphenyl)diphenylamine))] (TFB), di-[4-(N,N-di-p-tolyl-amino)-phenyl]cyclohexane (TAPC), 3,5-di(9H-carbazol-9-yl)-N,N-diphenylaniline (DCDPA), N-(biphenyl-4-yl)-9,9-dimethyl-N-(4-(9-phenyl-9H-carbazol-3-yl)phenyl)-9H-fluoren-2-amine, N-(biphenyl-4-yl)-N-(4-(9-phenyl-9H-carbazol-3-yl)phenyl)biphenyl-4-amine, and N-([1,1′-biphenyl]-4-yl)-9,9-dimethyl-N-(4-(9-phenyl-9H-carbazol-3-yl)phenyl)-9H-fluoren-2-amine, but it is not limited thereto. For example, the hole transporting material of each of the first HTL 313 and the second HTL 351 may be a compound in Formula 10. Each of the first HTL 313 and the second HTL 351 may have a thickness of 10 to 150 nm, preferably 30 to 120 nm. A thickness of the first HTL 313 may be smaller than that of the second HTL 351.

Each of the first ETL 319 and the second ETL 357 may include an electron transporting material being one of tris-(8-hydroxyquinoline aluminum (Alq3), 2-biphenyl-4-yl-5-(4-t-butylphenyl)-1,3,4-oxadiazole (PBD), spiro-PBD, lithium quinolate (Liq), 1,3,5-tris(N-phenylbenzimidazol-2-yl)benzene (TPBi), bis(2-methyl-8-quinolinolato-N1,08)-(1,1′-biphenyl-4-olato)aluminum (BAlq), 4,7-diphenyl-1,10-phenanthroline (Bphen), 2,9-bis(naphthalene-2-yl)-4,7-diphenyl-1,10-phenanthroline (NBphen), 2,9-dimethyl-4,7-diphenyl-1,10-phenathroline (BCP), 3-(4-biphenyl)-4-phenyl-5-tert-butylphenyl-1,2,4-triazole (TAZ), 4-(naphthalen-1-yl)-3,5-diphenyl-4H-1,2,4-triazole (NTAZ), 1,3,5-tri(p-pyrid-3-yl-phenyl)benzene (TpPyPB), 2,4,6-tris(3′-(pyridin-3-yl)biphenyl-3-yl)1,3,5-triazine (TmPPPyTz), poly[9,9-bis(3′-((N,N-dimethyl)-N-ethylammonium)-propyl)-2,7-fluorene]-alt-2,7-(9,9-dioctylfluorene)] (PFNBr), tris(phenylquinoxaline) (TPQ), diphenyl-4-triphenylsilyl-phenylphosphine oxide (TSPO1), and 2-[4-(9,10-Di-2-naphthalen2-yl-2-anthracen-2-yl)phenyl]-1-phenyl-1H-benzimidazole (ZADN). For example, the electron transporting material of each of the first ETL 319 and the second ETL 357 may be a compound in Formula 13. Each of the first ETL 319 and the second ETL 357 may have a thickness of 5 to 50 nm, preferably 10 to 40 nm. For example, a thickness of the first ETL 319 may be smaller than that of the second ETL 357.

The EIL 359 may include an electron injection material being one of Yb:LiF, LiF, CsF, NaF, BaF₂, Liq (lithium quinolate), lithium benzoate, and sodium stearate. The EIL 359 may have a thickness of 1 to 10 nm, preferably 3 to 8 nm.

Each of the first EBL 315 and the second EBL 353 may include an electron blocking material being one of TCTA, tris[4-(diethylamino)phenyl]amine, N-(biphenyl-4-yl)-9,9-dimethyl-N-(4-(9-phenyl-9H-carbazol-3-yl)phenyl)-9H-fluoren-2-amine, TAPC, MTDATA, 1,3-bis(carbazol-9-yl)benzene (mCP), 3,3′-bis(N-carbazolyl)-1,1′-biphenyl (mCBP), CuPc, N,N′-bis[4-[bis(3-methylphenyl)amino]phenyl]-N,N′-diphenyl-[1,1′-biphenyl]-4,4′-diamine (DNTPD), TDAPB, DCDPA, and 2,8-bis(9-phenyl-9H-carbazol-3-yl)dibenzo[b,d]thiophene), but it is not limited thereto. For example, the electron blocking material of each of the first EBL 315 and the second EBL 353 may be a compound in Formula 11. Each of the first and second EBLs 315 and 353 may have a thickness of 1 to 30 nm.

Each of the first HBL 317 and the second HBL 355 may include a hole blocking material being one of BCP, BAlq, Alq3, PBD, spiro-PBD, Liq, bis-4,6-(3,5-di-3-pyridylphenyl)-2-methylpyrimidine (B3PYMPM), bis[2-(diphenylphosphino)phenyl]ether oxide (DPEPO), 9-(6-9H-carbazol-9-yl)pyridine-3-yl)-9H-3,9′-bicarbazole, and TSPO1. For example, the electron blocking material of each of the first HBL and the second HBL 355 may be a compound in Formula 12. Each of the first and second HBLs 317 and 355 may have a thickness of 1 to 30 nm.

The CGL 390 is positioned between the first and second emitting parts 310 and 350, and the first and second emitting parts 310 and 350 are connected through the CGL 390. The first emitting part 310, the CGL 390, and the second emitting part 350 are sequentially stacked on the first electrode 210. Namely, the first emitting part 310 is positioned between the first electrode 210 and the CGL 390, and the second emitting part 350 is positioned between the second electrode 230 and the CGL 390.

The CGL 390 may be a P-N junction type CGL of an N-type CGL 392 and a P-type CGL 394. The N-type CGL 392 is positioned between the first ETL 319 and the second HTL 351, and the P-type CGL 394 is positioned between the N-type CGL 392 and the second HTL 351. The N-type CGL 392 provides an electron into the first EML 340 of the first emitting part 310, and the P-type CGL 394 provides a hole into the second EML 360 of the second emitting part 350.

The N-type CGL 392 may be an organic layer doped with an alkali metal, e.g., Li, Na, K and Cs, and/or an alkali earth metal, e.g., Mg, Sr, Ba and Ra. For example, the N-type CGL 392 may be formed of an N-type charge generation material including a host being the organic material, e.g., 4,7-dipheny-1,10-phenanthroline (Bphen) and MTDATA, a dopant being an alkali metal and/or an alkali earth metal, and the dopant may be doped with a weight % of 0.01 to 30. For example, the N-type CGL 392 may be formed by doping Li (e.g., 2 wt %) into an electron transporting material, e.g., the compound in Formula 13, and may have a thickness of 1 to 30 nm.

The P-type CGL 394 may be formed of a P-type charge generation material including an inorganic material, e.g., tungsten oxide (WOₓ), molybdenum oxide (MoOₓ), beryllium oxide (Be₂O₃) and vanadium oxide (V₂O₅), an organic material, e.g., NPD, HAT-CN, F4TCNQ, TPD, TNB, TCTA and N,N′-dioctyl-3,4,9,10-perylenedicarboximide (PTCDI-C8). For example, P-type CGL 394 may be formed of a hole injection material, e.g., the compound in Formula 9, and may have a thickness of 1 to 30 nm.

As described above, the OLED D1 of the present disclosure has a two-stack structure including the first emitting part 310, which includes the first EML 340 being a fluorescent emitting layer and having a double-layered structure, and the second emitting part 350, which includes the second EML 360 being a phosphorescent emitting layer and having a single-layered structure, between the first emitting part 310 and the second electrode 230.

In this case, the first EML 340 includes the first emitting layer 320, which includes the first fluorescent compound 322 and the first delayed fluorescent compound 324 and is disposed to be closer to the first electrode 210 as an anode, and the second emitting layer 330, which includes the second fluorescent compound 332 and the second delayed fluorescent compound 334 and is disposed to be closer to the second electrode 230 as a cathode. The first fluorescent compound 322 has a relatively low HOMO and LUMO energy levels and is represented by Formula 1, and the second fluorescent compound 332 has a relatively high HOMO and LUMO energy levels and is represented by Formula 3.

Accordingly, in the OLED D1 and the organic light emitting display device 100, the emitting efficiency and the lifespan are improved.

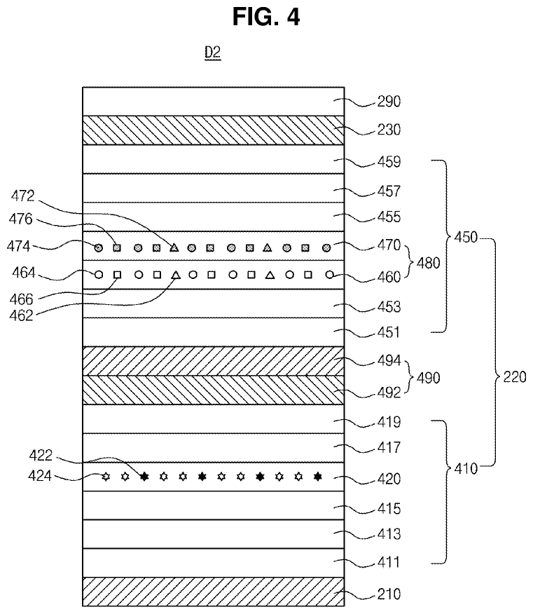

FIG. 4 is a schematic cross-sectional view of an OLED according to a third embodiment of the present disclosure.

As shown in FIG. 4, the OLED D2 includes the first electrode 210 as an anode for injecting a hole, the second electrode 230 as a cathode for injecting an electron facing the first electrode 210, and the organic light emitting layer 220 therebetween. The organic light emitting layer 220 includes a first emitting part 450 (e.g., a first green emitting part) including a first EML 480 (e.g., a first green EML), which has a double-layered structure including a first emitting layer 460 (e.g., a first green emitting layer) and a second emitting layer 470 (e.g., a second green emitting layer), and being disposed to be closer to the second electrode 230, and a second emitting part 410 (e.g., a second green emitting part) including a second EML 420 (e.g., a second green EML), which has a single-layered structure, and being disposed to be closer to the first electrode 210. In addition, the organic light emitting layer 220 may further include a CGL 490 between the first and second emitting parts 450 and 410. Moreover, the OLED D2 may further include a capping layer 290 for enhancing (improving) an emitting efficiency.

The organic light emitting display device may include a red pixel region, a green pixel region and a blue pixel region, and the OLED D2 is positioned in the green pixel region.

One of the first and second electrodes 210 and 230 may be a transparent electrode (e.g., a semitransparent electrode, and the other one of the first and second electrodes 210 and 230 may be a reflective electrode. For example, the first electrode 210 may be formed of ITO, and the second electrode 230 may be formed of MgAg. Each of the first and second electrodes 210 and 230 may have a thickness of 5 to 30 nm.

In the first emitting part 450, the first emitting layer 460 and the second emitting layer 470 contact each other. Namely, the first EML 480 in the first emitting part 450 has a double-layered structure.

The second emitting layer 470 is positioned between the second electrode 230 and the first emitting layer 460. Namely, the first emitting layer 460 is closer to the first electrode 210 as an anode, and the second emitting layer 470 is closer to the second electrode 230 as a cathode.

The first EML 480 may have a thickness of 20 to 60 nm, and each of the first and second emitting layers 460 and 470 may have a thickness of 10 to 50 nm. For example, the first and second emitting layers 460 and 470 may have the same thickness.

The first emitting layer 460 includes a first fluorescent compound 462 and a first delayed fluorescent compound 464. The first emitting layer 460 may further include a first host 466.

In the first emitting layer 460, the first fluorescent compound 462 serves as an emitter (e.g., a dopant), and the first delayed fluorescent compound 464 serves as an auxiliary dopant or an auxiliary host. For example, in the first emitting layer 460, an exciton generated in the first host 466 may be transferred to the first fluorescent compound 462 through the first delayed fluorescent compound 464 so that the emission may be provided from the first fluorescent compound 462.

In the first emitting layer 460, the first fluorescent compound 462 has a first weight %, and each of a second weight % of the first delayed fluorescent compound 464 and a third weight % of the first host 466 is greater than the first weight %. The second weight % of the first delayed fluorescent compound 464 and the third weight % of the first host 466 may be same or different. For example, in the first emitting layer 460, the first delayed fluorescent compound 464 and the first host 466 may have the same weight %, and the first fluorescent compound 462 may have a weight % of 0.1 to 10, preferably 0.2 to 2.0.

The second emitting layer 470 includes a second fluorescent compound 472 and a second delayed fluorescent compound 474. The second emitting layer 470 may further include a second host 476.

In the second emitting layer 470, the second fluorescent compound 472 serves as an emitter (e.g., a dopant), and the second delayed fluorescent compound 474 serves as an auxiliary dopant or an auxiliary host. For example, in the second emitting layer 470, an exciton generated in the second host 476 may be transferred to the second fluorescent compound 472 through the second delayed fluorescent compound 474 so that the emission may be provided from the second fluorescent compound 472.

In the second emitting layer 470, the second fluorescent compound 472 has a fourth weight %, and each of a fifth weight % of the second delayed fluorescent compound 474 and a sixth weight % of the second host 476 is greater than the fourth weight %. The fifth weight % of the second delayed fluorescent compound 474 and the sixth weight % of the first host 476 may be same or different. For example, in the second emitting layer 470, the second delayed fluorescent compound 474 and the second host 476 may have the same weight %, and the second fluorescent compound 472 may have a weight % of 0.1 to 10, preferably 0.2 to 2.0.

The first weight % of the first fluorescent compound 462 in the first emitting layer 460 may be greater than the fourth weight % of the second fluorescent compound 472 in the second emitting layer 470. For example, the first weight % of the first fluorescent compound 462 may be in a range of 0.7 to 2.0, and the fourth weight % of the second fluorescent compound 472 may be in a range of 0.2 to 0.7.

The first fluorescent compound 462 in the first emitting layer 460 is a boron derivative having a first highest occupied molecular orbital (HOMO) energy level and a first lowest unoccupied molecular orbital (LUMO) energy level. The first fluorescent compound 462 is represented by Formula 1 or Formula 1a and may be one of the compounds in Formula 2.

The second fluorescent compound 472 in the second emitting layer 470 is a boron derivative having a second HOMO energy level, which is higher than the first HOMO energy level, and a second LUMO energy level, which is higher than the first LUMO energy level. The second fluorescent compound 472 is represented by Formula 3 and may be one of the compounds in Formula 4.

Each of the first delayed fluorescent compound 464 in the first emitting layer 460 and the second delayed fluorescent compound 474 in the second emitting layer 470 is independently selected from the compounds in Formula 5. The first delayed fluorescent compound 464 and the second delayed fluorescent compound 474 may be same or different.

Each of the first host 466 in the first emitting layer 460 and the second host 476 in the second emitting layer 470 is independently selected from the compounds in Formula 6. The first host 466 and the second host 476 may be same or different.

The first emitting part 450 may further include at least one of a first HTL 451 under the first EML 480 and a first ETL 457 on the first EML 480.

In addition, the first emitting part 450 may further include an EIL 459 on the first ETL 457.

Moreover, the first emitting part 450 may further include at least one of a first EBL 453 between the first EML 480 and the first HTL 451 and a first HBL 455 between the first EML 480 and the first ETL 457.

In the second emitting part 410, the second EML 420 has a single-layered structure and may have a thickness of 20 to 60 nm.

The second EML 420 includes a phosphorescent compound 422 as a dopant (e.g., an emitter). In addition, the second EML 420 may further include a third host 424.

In the second EML 420, the phosphorescent compound 422 has a seventh weight %, and the third host 424 has an eighth weight % being greater than the seventh weight %. For example, in the second EML 420, the phosphorescent compound 422 may have a weight % of 1 to 5, and the third host 424 may have a weight % of 95 to 99.

The phosphorescent compound 422 in the second EML 420 may be one of the compounds in Formula 7, and the third host 424 in the second EML 420 may be one of the compounds in Formula 8.

The second emitting part 410 may further include at least one of a second HTL 413 under the second EML 420 and a second ETL 419 on the second EML 420.

In addition, the second emitting part 410 may further include an HIL 411 under the second HTL 413.

Moreover, the second emitting part 410 may further include at least one of a second EBL 415 between the second EML 420 and the second HTL 413 and a second HBL 417 between the second EML 420 and the second ETL 419.

The HIL 411 may include the above-mentioned hole injection material and may have a thickness of 1 to 20 nm.

Each of the first and second HTLs 451 and 413 may include the above-mentioned hole transporting material and may have a thickness of 10 to 150 nm, preferably 30 to 120 nm. A thickness of the second HTL 413 may be smaller than that of the first HTL 451.

Each of the first and second ETLs 457 and 419 may include the above-mentioned electron transporting material and may have a thickness of 5 to 50 nm, preferably 10 to 40 nm. A thickness of the second ETL 419 may be smaller than that of the first ETL 457.

The EIL 459 may include the above-mentioned electron injection material and may have a thickness of 1 to 10 nm, preferably 3 to 8 nm.

Each of the first and second EBLs 453 and 415 may include the above-mentioned electron blocking material and may have a thickness of 1 to 30 nm.

Each of the first and second HBLs 455 and 417 may include the above-mentioned hole blocking material and may have a thickness of 1 to 30 nm.

The CGL 490 is positioned between the first and second emitting parts 450 and 410, and the first and second emitting parts 450 and 410 are connected through the CGL 490. The second emitting part 410, the CGL 490, and the first emitting part 450 are sequentially stacked on the first electrode 210. Namely, the second emitting part 410 is positioned between the first electrode 210 and the CGL 490, and the first emitting part 450 is positioned between the second electrode 230 and the CGL 490.

The CGL 490 may be a P-N junction type CGL of an N-type CGL 492 and a P-type CGL 494. The N-type CGL 492 is positioned between the second ETL 419 and the first HTL 451, and the P-type CGL 494 is positioned between the N-type CGL 492 and the first HTL 451. The N-type CGL 492 provides an electron into the second EML 420 of the second emitting part 410, and the P-type CGL 494 provides a hole into the first EML 480 of the first emitting part 450.

The N-type CGL 492 may include the above-mentioned N-type charge generation material and may have a thickness of 1 to 30 nm.

The P-type CGL 494 may include the above-mentioned P-type charge generation material and may have a thickness of 1 to 30 nm.

As described above, the OLED D2 of the present disclosure has a two-stack structure including the first emitting part 450, which includes the first EML 480 being a fluorescent emitting layer and having a double-layered structure, and the second emitting part 410, which includes the second EML 420 being a phosphorescent emitting layer and having a single-layered structure, between the first emitting part 450 and the first electrode 210.

In this case, the first EML 480 includes the first emitting layer 460, which includes the first fluorescent compound 462 and the first delayed fluorescent compound 464 and is disposed to be closer to the first electrode 210 as an anode, and the second emitting layer 470, which includes the second fluorescent compound 472 and the second delayed fluorescent compound 474 and is disposed to be closer to the second electrode 230 as a cathode. The first fluorescent compound 462 has a relatively low HOMO and LUMO energy levels and is represented by Formula 1, and the second fluorescent compound 472 has a relatively high HOMO and LUMO energy levels and is represented by Formula 3.

Accordingly, in the OLED D2 and the organic light emitting display device 100, the emitting efficiency and the lifespan are improved.

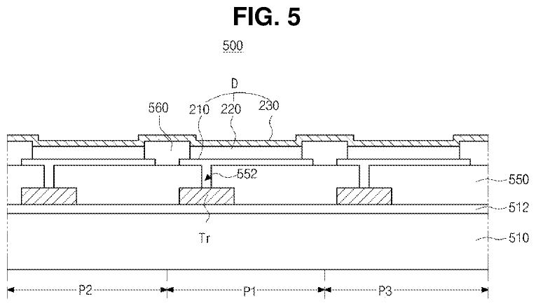

FIG. 5 is a schematic cross-sectional view of an organic light emitting display device according to a fourth embodiment of the present disclosure.

As shown in FIG. 5, the organic light emitting display device 500 includes a substrate 510, wherein first to third pixel regions P1, P2 and P3 are defined, a TFT Tr over the substrate 510 and an OLED D. The OLED D is disposed over the TFT Tr and is connected to the TFT Tr.

For example, the first to third pixel regions P1, P2 and P3 may be a green pixel region, a red pixel region and a blue pixel region, respectively. The first to third pixel regions P1, P2 and P3 constitute a pixel unit. Alternatively, the pixel unit may further include a white pixel region.

The substrate 510 may be a glass substrate or a flexible substrate.

A buffer layer 512 is formed on the substrate 510, and the TFT Tr is formed on the buffer layer 512. The buffer layer 512 may be omitted.

The TFT Tr is positioned on the buffer layer 512. The TFT Tr includes a semiconductor layer, a gate electrode, a source electrode and a drain electrode and acts as a driving element. Namely, the TFT Tr may be the driving TFT Td (of FIG. 1).

A planarization layer (or passivation layer) 550 is formed on the TFT Tr. The planarization layer 550 has a flat top surface and includes a drain contact hole 552 exposing the drain electrode of the TFT Tr.

The OLED D is disposed on the planarization layer 550 and includes a first electrode 210, an organic light emitting layer 220 and a second electrode 230. The first electrode 210 is connected to the drain electrode of the TFT Tr, and the organic light emitting layer 220 and the second electrode 230 are sequentially stacked on the first electrode 210. The OLED D is disposed in each of the first to third pixel regions P1 to P3 and emits different color light in the first to third pixel regions P1 to P3. For example, the OLED D in the first pixel region P1 may emit the green light, the OLED D in the second pixel region P2 may emit the red light, and the OLED D in the third pixel region P3 may emit the blue light.

The first electrode 210 is formed to be separate in the first to third pixel regions P1 to P3, and the second electrode 230 is formed as one-body to cover the first to third pixel regions P1 to P3.

The first electrode 210 is an anode, and the second electrode 230 is a cathode. In addition, the first electrode 210 is a transparent electrode (or a semi-transparent electrode), and the second electrode 230 is a reflective electrode. Namely, the light from the OLED D passes through the first electrode 210 to display an image on the substrate 510 (i.e., a bottom-emission type organic light emitting display device).

For example, the first electrode 210 may be an anode and may include a conductive material, e.g., a transparent conductive oxide (TCO), having a relatively high work function, and a reflection layer.

The second electrode 230 may a cathode and may be formed of a conductive material having a relatively low work function.

In the OLED D in the first pixel region P1, the organic light emitting layer 220 may have a structure of FIG. 3 or FIG. 4.

Referring to FIG. 3, the organic light emitting layer 220 includes the first emitting part 310 including the first EML 340, which has a double-layered structure and is a fluorescent emitting layer, and the second emitting part 350 including the second EML 360, which has a single-layered structure and is a phosphorescent emitting layer, between the first emitting part 310 and the second electrode 230, so that the OLED D has a two-stack structure.

In this case, the first EML 340 includes the first emitting layer 320, which includes the first fluorescent compound 322 and the first delayed fluorescent compound 324 and is disposed to be closer to the first electrode 210 as an anode, and the second emitting layer 330, which includes the second fluorescent compound 332 and the second delayed fluorescent compound 334 and is disposed to be closer to the second electrode 230 as a cathode. The first fluorescent compound 322 has a relatively low HOMO and LUMO energy levels and is represented by Formula 1, and the second fluorescent compound 332 has a relatively high HOMO and LUMO energy levels and is represented by Formula 3.

Referring to FIG. 4, the organic light emitting layer 220 includes the first emitting part 450 including the first EML 480, which has a double-layered structure and is a fluorescent emitting layer, and the second emitting part 410 including the second EML 420, which has a single-layered structure and is a phosphorescent emitting layer, between the first emitting part 450 and the first electrode 210, so that the OLED D has a two-stack structure.

In this case, the first EML 480 includes the first emitting layer 460, which includes the first fluorescent compound 462 and the first delayed fluorescent compound 464 and is disposed to be closer to the first electrode 210 as an anode, and the second emitting layer 470, which includes the second fluorescent compound 472 and the second delayed fluorescent compound 474 and is disposed to be closer to the second electrode 230 as a cathode. The first fluorescent compound 462 has a relatively low HOMO and LUMO energy levels and is represented by Formula 1, and the second fluorescent compound 472 has a relatively high HOMO and LUMO energy levels and is represented by Formula 3.

In the OLED D in the second pixel region P2, the organic light emitting layer 220 includes a red EML, and the red EML may include a red host and a red dopant.

For example, the red host may include at least one of mCP-CN, CBP, mCBP, mCP, DPEPO, 2,8-bis(diphenylphosphoryl)dibenzothiophene (PPT), 1,3,5-tri[(3-pyridyl)-phen-3-yl]benzene (TmPyPB), 2,6-di(9H-carbazol-9-yl)pyridine (PYD-2Cz), 2,8-di(9H-carbazol-9-yl)dibenzothiophene (DCzDBT), 3′,5′-di(carbazol-9-yl)-[1,1′-bipheyl]-3,5-dicarbonitrile (DCzTPA), 4′-(9H-carbazol-9-yl)biphenyl-3,5-dicarbonitrile (pCzB-2CN), 3′-(9H-carbazol-9-yl)biphenyl-3,5-dicarbonitrile (mCzB-2CN), TSPO1, 9-(9-phenyl-9H-carbazol-6-yl)-9H-carbazole (CCP), 4-(3-(triphenylen-2-yl)phenyl)dibenzo[b,d]thiophene, 9-(4-(9H-carbazol-9-yl)phenyl)-9H-3,9′-bicarbazole, 9-(3-(9H-carbazol-9-yl)phenyl)-9H-3,9′-bicarbazole, 9-(6-(9H-carbazol-9-yl)pyridin-3-yl)-9H-3,9′-bicabazole, 9,9′-Diphenyl-9H,9′H-3,3′-bicarbazole (BCzPh), 1,3,5-tris(carbazole-9-yl)benzene (TCP), TCTA, 4,4′-bis(carbazole-9-yl)-2,2′-dimethylbipheyl (CDBP), 2,7-bis(carbazole-9-yl)-9,9-dimethylfluorene (DMFL-CBP), 2,2′, 7,7′-tetrakis(carbazole-9-yl)-9,9-spiorofluorene (Spiro-CBP), and 3,6-bis(carbazole-9-yl)-9-(2-ethyl-hexyl)-9H-carbazole; TCz1), but it is not limited thereto.

For example, the red dopant may include at least one of [bis(2-(4,6-dimethyl)phenylquinoline)](2,2,6,6-tetramethylheptane-3,5-dionate)iridium(III), bis[2-(4-n-hexylphenyl)quinoline](acetylacetonate)iridium(III) (Hex-Ir(phq)₂(acac)), tris[2-(4-n-hexylphenyl)quinoline]iridium(III) (Hex-Ir(phq)₃), tris[2-phenyl-4-methylquinoline]iridium(III) (Ir(Mphq)₃), bis(2-phenylquinoline)(2,2,6,6-tetramethylheptene-3,5-dionate)iridium(III) (Ir(dpm)PQ₂), bis(phenylisoquinoline)(2,2,6,6-tetramethylheptene-3,5-dionate)iridium(III) (Ir(dpm)(piq)₂), bis[(4-n-hexylphenyl)isoquinoline](acetylacetonate)iridium(III) (Hex-Ir(piq)₂(acac)), tris[2-(4-n-hexylphenyl)quinoline]iridium(III) (Hex-Ir(piq)₃), tris(2-(3-methylphenyl)-5-methyl-quinolato)iridium (Ir(dmpq)₃), bis[2-(2-methylphenyl)-5-methyl-quinoline](acetylacetonate)iridium(III) (Ir(dmpq)₂(acac)), bis[2-(3,5-dimethylphenyl)-4-methyl-quinoline](acetylacetonate)iridium(III) (Ir(mphmq)₂(acac)), and tris(dibenzoylmethane)mono(1,10-phenanthroline)europium(III) (Eu(dbm)₃(phen)), but it is not limited thereto.

In the OLED D in the third pixel region P3, the organic light emitting layer 220 includes a blue EML, and the blue EML may include a blue host and a blue dopant.

For example, the blue host may include at least one of mCP, mCP-CN, mCBP, CBP-CN, CBP, 9-(3-(9H-carbazol-9-yl)phenyl)-3-(diphenylphosphoryl)-9H-carbazole (mCPPO1), 3,5-di(9H-carbazol-9-yl)biphenyl (Ph-mCP), TSPO1, 9-(3′-(9H-carbazol-9-yl)-[1,1′-biphenyl]-3-yl)-9H-pyrido[2,3-b]indole (CzBPCb), bis(2-methylphenyl)diphenylsilane (UGH-1), 1,4-bis(triphenylsilyl)benzene (UGH-2), 1,3-bis(triphenylsilyl)benzene (UGH-3), 9,9-spirobifluoren-2-yl-diphenyl-phosphine oxide (SPPO1), and 9,9′-(5-(triphenylsilyl)-1,3-phenylene)bis(9H-carbazole) (SimCP), but it is not limited thereto.

For example, the blue dopant may include at least one of perylene, 4,4′-bis[4-(di-p-tolylamino)styryl]biphenyl (DPAVBi), 4-(di-p-tolylamino)-4-4′-[(di-p-tolylamino)styryl]stilbene (DPAVB), 4,4′-bis[4-(diphenylamino)styryl]biphenyl (BDAVBi), 2,5,8,11-Tetra-tetr-butylperylene (TBPe), Bepp2, 9-(9-phenylcarbazole-3-yl)-10-(naphthalene-1-yl)anthracene (PCAN), mer-tris(1-phenyl-3-methylimidazolin-2-ylidene-C,C(2)′ iridium(III) (mer-Ir(pmi)₃), fac-tris(1,3-diphenyl-benzimidazolin-2-ylidene-C,C(2)′ iridium(III) (fac-Ir(dpbic)₃), bis(3,4,5-trifluoro-2-(2-pyridyl)phenyl-(2-carboxypyridyl)iridium(III) (Ir(tfpd)₂pic), tris(2-(4,6-difluorophenyl)pyridine))iridium(III) (Ir(Fppy)₃), and bis[2-(4,6-difluorophenyl)pyridinato-C2,N](picolinato)iridium(III) (FIrpic), but it is not limited thereto.

Although not shown, the OLED D may further include a capping layer on the second electrode 230. The optical efficiency of the OLED D and the organic light emitting display device 500 may be further improved.

An encapsulation layer (or an encapsulation film) may be formed on the second electrode 230 to prevent penetration of moisture into the OLED D. The encapsulation layer may have a structure including an inorganic insulating layer and an organic insulating layer.

A metal plate may be further disposed on the encapsulation layer.

Although not shown, the organic light emitting display device 500 may include a color filter corresponding to the first to third pixel regions P1, P2 and P3. For example, the color filter may be positioned between the OLED D and the substrate 510.

### [OLED1]

An anode (ITO, 10 nm), an HIL (the compound in Formula 9, 7 nm), a first HTL (the compound in Formula 10, 30 nm), a first EBL (the compound in Formula 11, 10 nm), a first EML (40 nm), a first HBL (the compound in Formula 12, 10 nm), a first ETL (the compound in Formula 13, 15 nm), an N-type CGL (the compound in Formula 13 and Li (2 wt %), 10 nm), a P-type CGL (the compound in Formula 9, 8 nm), a second HTL (the compound in Formula 10, 70 nm), a second EBL (the compound in Formula 11, 10 nm), a first emitting layer (20 nm), a second emitting layer (20 nm), a second HBL (the compound in Formula 12, 10 nm), a second ETL (the compound in Formula 13, 30 nm), an EIL (Yb:LiF, 5 nm), a cathode (AgMg, 15 nm) and a capping layer (the compound in Formula 10, 100 nm) were sequentially deposited to form an OLED in the green pixel region.

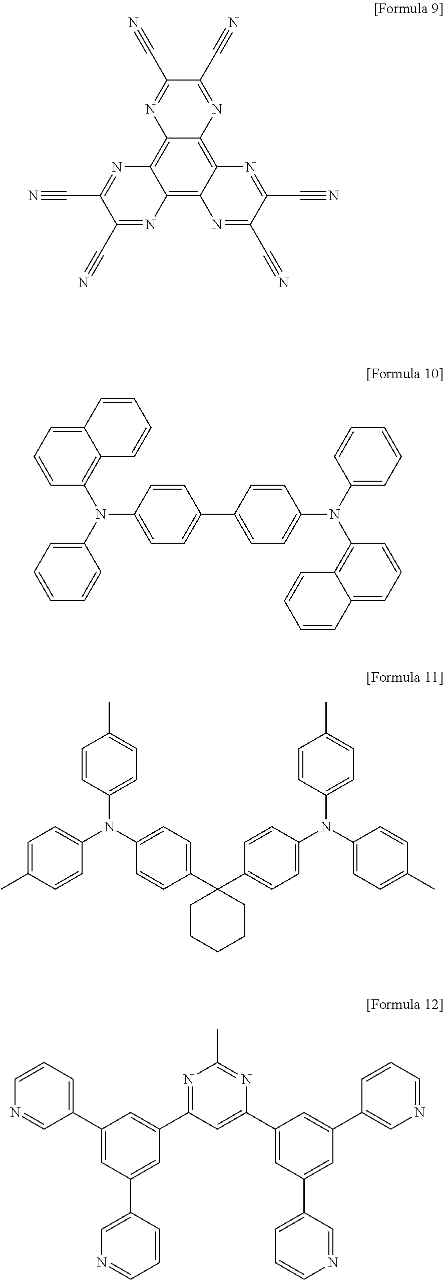

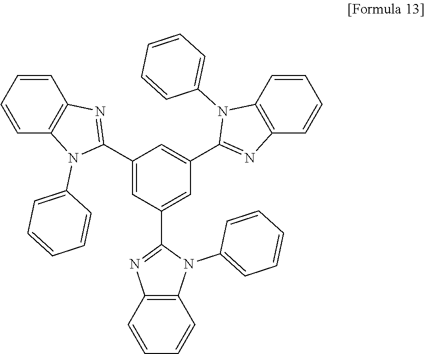 [SMILES: c1ccc(-n2c(-c3cc(-c4nc5ccccc5n4-c4ccccc4)cc(-c4nc5ccccc5n4-c4ccccc4)c3)nc3ccccc32)cc1]

### 1. Comparative Examples

### (1) Comparative Example 1 (Ref1)

The compound PH-1 (98 wt %) in Formula 8 and the compound PD-1 (2 wt %) in Formula 7 were used to form the first EML. The compound B-1 (0.5 wt %) in Formula 4, the compound TD-1 (49.75 wt %) in Formula 5 and the compound FH-1 (49.75 wt %) in Formula 6 were used to form the first emitting layer, and the compound A-1 (1.0 wt %) in Formula 2, the compound TD-1 (49.5 wt %) in Formula 5 and the compound FH-1 (49.5 wt %) in Formula 6 were used to form the second emitting layer.

### (2) Comparative Example 2 (Ref2)

The compound PH-1 (98 wt %) in Formula 8 and the compound PD-1 (2 wt %) in Formula 7 were used to form the first EML. The compound A-1 (1.0 wt %) in Formula 2, the compound TD-1 (49.5 wt %) in Formula 5 and the compound FH-1 (49.5 wt %) in Formula 6 were used to form the first and second emitting layers.

### (3) Comparative Example 3 (Ref3)

The compound PH-1 (98 wt %) in Formula 8 and the compound PD-1 (2 wt %) in Formula 7 were used to form the first EML. The compound B-1 (0.5 wt %) in Formula 4, the compound TD-1 (49.75 wt %) in Formula 5 and the compound FH-1 (49.75 wt %) in Formula 6 were used to form the first and second emitting layers.

### (4) Comparative Example 4 (Ref4)

The compound PH2 (98 wt %) in Formula 8 and the compound PD-2 (2 wt %) in Formula 7 were used to form the first EML. The compound B-1 (0.5 wt %) in Formula 4, the compound TD-1 (49.75 wt %) in Formula 5 and the compound FH-1 (49.75 wt %) in Formula 6 were used to form the first emitting layer, and the compound A-1 (1.0 wt %) in Formula 2, the compound TD-1 (49.5 wt %) in Formula 5 and the compound FH-1 (49.5 wt %) in Formula 6 were used to form the second emitting layer.

### (5) Comparative Example 5 (Ref5)

The compound PH-2 (98 wt %) in Formula 8 and the compound PD-2 (2 wt %) in Formula 7 were used to form the first EML. The compound A-1 (1.0 wt %) in Formula 2, the compound TD-1 (49.5 wt %) in Formula 5 and the compound FH-1 (49.5 wt %) in Formula 6 were used to form the first and second emitting layers.

### (6) Comparative Example 6 (Ref6)

The compound PH-2 (98 wt %) in Formula 8 and the compound PD-2 (2 wt %) in Formula 7 were used to form the first EML. The compound B-1 (0.5 wt %) in Formula 4, the compound TD-1 (49.75 wt %) in Formula 5 and the compound FH-1 (49.75 wt %) in Formula 6 were used to form the first and second emitting layers.

### (7) Comparative Example 7 (Ref7)

The compound PH-1 (98 wt %) in Formula 8 and the compound PD-1 (2 wt %) in Formula 7 were used to form the first EML. The compound B-2 (0.5 wt %) in Formula 4, the compound TD-1 (49.75 wt %) in Formula 5 and the compound FH-1 (49.75 wt %) in Formula 6 were used to form the first emitting layer, and the compound A-2 (1.0 wt %) in Formula 2, the compound TD-1 (49.5 wt %) in Formula 5 and the compound FH-1 (49.5 wt %) in Formula 6 were used to form the second emitting layer.

### (8) Comparative Example 8 (Ref8)

The compound PH-1 (98 wt %) in Formula 8 and the compound PD-1 (2 wt %) in Formula 7 were used to form the first EML. The compound A-2 (1.0 wt %) in Formula 2, the compound TD-1 (49.5 wt %) in Formula 5 and the compound FH-1 (49.5 wt %) in Formula 6 were used to form the first and second emitting layers.

### (9) Comparative Example 9 (Ref9)

The compound PH-1 (98 wt %) in Formula 8 and the compound PD-1 (2 wt %) in Formula 7 were used to form the first EML. The compound B-2 (0.5 wt %) in Formula 4, the compound TD-1 (49.75 wt %) in Formula 5 and the compound FH-1 (49.75 wt %) in Formula 6 were used to form the first and second emitting layers.

### (10) Comparative Example 10 (Ref10)

The compound PH-2 (98 wt %) in Formula 8 and the compound PD-2 (2 wt %) in Formula 7 were used to form the first EML. The compound B-2 (0.5 wt %) in Formula 4, the compound TD-1 (49.75 wt %) in Formula 5 and the compound FH-1 (49.75 wt %) in Formula 6 were used to form the first emitting layer, and the compound A-2 (1.0 wt %) in Formula 2, the compound TD-1 (49.5 wt %) in Formula 5 and the compound FH-1 (49.5 wt %) in Formula 6 were used to form the second emitting layer.

### (11) Comparative Example 11 (Ref11)

The compound PH-2 (98 wt %) in Formula 8 and the compound PD-2 (2 wt %) in Formula 7 were used to form the first EML. The compound A-2 (1.0 wt %) in Formula 2, the compound TD-1 (49.5 wt %) in Formula 5 and the compound FH-1 (49.5 wt %) in Formula 6 were used to form the first and second emitting layers.

### (12) Comparative Example 12 (Ref12)

The compound PH-2 (98 wt %) in Formula 8 and the compound PD-2 (2 wt %) in Formula 7 were used to form the first EML. The compound B-2 (0.5 wt %) in Formula 4, the compound TD-1 (49.75 wt %) in Formula 5 and the compound FH-1 (49.75 wt %) in Formula 6 were used to form the first and second emitting layers.

### 2. Examples

### (1) Example 1 (Ex1)

The compound PH-1 (98 wt %) in Formula 8 and the compound PD-1 (2 wt %) in Formula 7 were used to form the first EML. The compound A-1 (1.0 wt %) in Formula 2, the compound TD-1 (49.5 wt %) in Formula 5 and the compound FH-1 (49.5 wt %) in Formula 6 were used to form the first emitting layer, and the compound B-1 (0.5 wt %) in Formula 4, the compound TD-1 (49.75 wt %) in Formula 5 and the compound FH-1 (49.75 wt %) in Formula 6 were used to form the second emitting layer.

### (2) Example 2 (Ex2)

The compound PH-2 (98 wt %) in Formula 8 and the compound PD-2 (2 wt %) in Formula 7 were used to form the first EML. The compound A-1 (1.0 wt %) in Formula 2, the compound TD-1 (49.5 wt %) in Formula 5 and the compound FH-1 (49.5 wt %) in Formula 6 were used to form the first emitting layer, and the compound B-1 (0.5 wt %) in Formula 4, the compound TD-1 (49.75 wt %) in Formula 5 and the compound FH-1 (49.75 wt %) in Formula 6 were used to form the second emitting layer.

### (3) Example 3 (Ex3)

The compound PH-1 (98 wt %) in Formula 8 and the compound PD-1 (2 wt %) in Formula 7 were used to form the first EML. The compound A-2 (1.0 wt %) in Formula 2, the compound TD-1 (49.5 wt %) in Formula 5 and the compound FH-1 (49.5 wt %) in Formula 6 were used to form the first emitting layer, and the compound B-2 (0.5 wt %) in Formula 4, the compound TD-1 (49.75 wt %) in Formula 5 and the compound FH-1 (49.75 wt %) in Formula 6 were used to form the second emitting layer.

### (4) Example 4 (Ex4)

The compound PH-2 (98 wt %) in Formula 8 and the compound PD-2 (2 wt %) in Formula 7 were used to form the first EML. The compound A-2 (1.0 wt %) in Formula 2, the compound TD-1 (49.5 wt %) in Formula 5 and the compound FH-1 (49.5 wt %) in Formula 6 were used to form the first emitting layer, and the compound B-2 (0.5 wt %) in Formula 4, the compound TD-1 (49.75 wt %) in Formula 5 and the compound FH-1 (49.75 wt %) in Formula 6 were used to form the second emitting layer.

A HOMO energy level and a LUMO energy level of the fluorescent compounds used in Comparative Examples 1 to 12 and Examples 1 to 4 were measured and listed in Table 1.

Various methods of determining the HOMO energy level are known to the skilled person. For example, the HOMO energy level can be determined using a conventional surface analyzer such as an AC3 surface analyzer made by RKI instruments. The surface analyzer may be used to interrogate a single film (neat film) of a compound with a thickness of 50 nm. The LUMO energy level can be calculated as follows:

LUMO=HOMO−bandgap.

The bandgap may be calculated using any conventional method known to the skilled person, such as from a UV-vis measurement of a single film with a thickness of 50 nm. For example, this can be done using a SCINCO S-3100 spectrophotometer. The HOMO and LUMO values of the compounds of the examples and embodiments disclosed herein may be determined in this way. Namely, the HOMO and LUMO values may be experimentally or empirically determined values of thin films, such as 50 nm films.

TABLE 1

| | HOMO (eV) | LUMO (eV) |
|---|---|---|
| Compound A-1 | −5.94 | −3.55 |
| Compound A-2 | −5.99 | −3.68 |
| Compound B-1 | −5.59 | −3.32 |
| Compound B-2 | −5.63 | −3.38 |

As shown in Table 1, the first fluorescent compound represented by Formula 1 has a relatively low HOMO and LUMO energy levels, and the second fluorescent compound represented by Formula 3 has a relatively high HOMO and LUMO energy levels. Namely, the first fluorescent compound represented by Formula 1 has a first HOMO energy level and a first LUMO energy level, and the second fluorescent compound represented by Formula 3 has a second HOMO energy level being higher than the first HOMO energy level and a second LUMO energy level being higher than the first LUMO energy level.

For example, the first HOMO energy level of the first fluorescent compound may be in a range of −6.0 to −5.8 eV, and the second HOMO energy level of the second fluorescent compound may be in a range of −5.7 to −5.5 eV. The first LUMO energy level of the first fluorescent compound may be in a range of −3.8 to −3.5 eV, and the second LUMO energy level of the second fluorescent compound may be in a range of −3.5 to −3.2 eV.

The properties, i.e., a driving voltage (V), a brightness (cd/A), a color coordinate (CIE), a maximum emission peak (ELₘₐₓ, nm), a full-width at half maximum (FWHM, nm) and a lifespan (T₉₅, hour), of the OLED in Comparative Examples 1 to 12 and Examples 1 to 4 were measured and listed in Table 2.

TABLE 2

| | | V | cd/A | (CIEx, CIEy) | ELₘₐₓ | FWHM | T₉₅ |
|---|---|---|---|---|---|---|---|
| Ref1 | PD-1/(B-1:A-1) | 6.09 | 304.2 | (0.231, 0.730) | 530 | 24 | 1370 |
| Ref2 | PD-1/(A-1:A-1) | 5.56 | 317.9 | (0.242, 0.718) | 528 | 29 | 1000 |
| Ref3 | PD-1/(B-1:B-1) | 6.11 | 291.5 | (0.223, 0.732) | 530 | 24 | 1600 |
| Ex1 | PD-1/(A-1:B-1) | 5.98 | 331.4 | (0.239, 0.723) | 532 | 27 | 2000 |
| Ref4 | PD-2/(B-1:A-1) | 6.41 | 300.2 | (0.227, 0.732) | 350 | 25 | 1300 |
| Ref5 | PD-2/(A-1:A-1) | 5.65 | 312.9 | (0.237, 0.723) | 530 | 27 | 990 |
| Ref6 | PD-2/(B-1:B-1) | 5.98 | 295.2 | (0.223, 0.734) | 530 | 23 | 1520 |
| Ex2 | PD-2/(A-1:B-1) | 5.88 | 322.1 | (0.238, 0.720) | 528 | 27 | 1870 |
| Ref7 | PD-1/(B-2:A-2) | 6.12 | 301.3 | (0.224, 0.735) | 530 | 23 | 1240 |
| Ref8 | PD-1/(A-2:A-2) | 5.59 | 310.8 | (0.240, 0.718) | 530 | 27 | 1050 |
| Ref9 | PD-1/(B-2:B-2) | 6.05 | 279.5 | (0.240, 0.721) | 530 | 26 | 1470 |
| Ex3 | PD-1/(A-2:B-2) | 5.77 | 325.1 | (0.237, 0.723) | 530 | 27 | 1900 |
| Ref10 | PD-2/(B-2:A-2) | 5.79 | 293.8 | (0.305, 0.671) | 536 | 47 | 1150 |
| Ref11 | PD-2/(A-2:A-2) | 5.58 | 318.6 | (0.252, 0.715) | 532 | 25 | 950 |
| Ref12 | PD-2/(B-2:B-2) | 5.59 | 292.0 | (0.249, 0.715) | 532 | 27 | 1350 |
| Ex4 | PD-2/(A-2:B-2) | 5.62 | 320.5 | (0.249, 0.714) | 530 | 29 | 1730 |

As shown in Table 2, in comparison to the OLED of Comparative Examples 1 to 12, the emitting efficiency and the lifespan of the OLED of Examples 1 to 4 are improved.

For example, in comparison to the OLED of Comparative Examples 1, 4, 7 and 10, in which a fluorescent compound in Formula 3 having a relatively high HOMO and LUMO energy levels is included in the first emitting layer being closer to the anode, in the OLED of Examples 1 to 4, in which a fluorescent compound in Formula 3 having a relatively high HOMO and LUMO energy levels is included in the second emitting layer being closer to the cathode, the emitting efficiency and the lifespan are significantly improved.

### [OLED2]

An anode (ITO, 10 nm), an HIL (the compound in Formula 9, 7 nm), a first HTL (the compound in Formula 10, 30 nm), a first EBL (the compound in Formula 11, 10 nm), a first emitting layer (20 nm), a second emitting layer (20 nm), a first HBL (the compound in Formula 12, 10 nm), a first ETL (the compound in Formula 13, 15 nm), an N-type CGL (the compound in Formula 13 and Li (2 wt %), 10 nm), a P-type CGL (the compound in Formula 9, 8 nm), a second HTL (the compound in Formula 10, 70 nm), a second EBL (the compound in Formula 11, 10 nm), a second EML (40 nm), a second HBL (the compound in Formula 12, 10 nm), a second ETL (the compound in Formula 13, 30 nm), an EIL (Yb:LiF, 5 nm), a cathode (AgMg, 15 nm) and a capping layer (the compound in Formula 10, 100 nm) were sequentially deposited to form an OLED in the green pixel region.

### 3. Comparative Examples

### (1) Comparative Example 13 (Ref13)

The compound B-1 (0.5 wt %) in Formula 4, the compound TD-1 (49.75 wt %) in Formula 5 and the compound FH-1 (49.75 wt %) in Formula 6 were used to form the first emitting layer, and the compound A-1 (1.0 wt %) in Formula 2, the compound TD-1 (49.5 wt %) in Formula 5 and the compound FH-1 (49.5 wt %) in Formula 6 were used to form the second emitting layer. The compound PH-1 (98 wt %) in Formula 8 and the compound PD-1 (2 wt %) in Formula 7 were used to form the second EML.

### (2) Comparative Example 14 (Ref14)

The compound B-1 (0.5 wt %) in Formula 4, the compound TD-1 (49.75 wt %) in Formula 5 and the compound FH-1 (49.75 wt %) in Formula 6 were used to form the first emitting layer, and the compound A-1 (1.0 wt %) in Formula 2, the compound TD-1 (49.5 wt %) in Formula 5 and the compound FH-1 (49.5 wt %) in Formula 6 were used to form the second emitting layer. The compound PH-2 (98 wt %) in Formula 8 and the compound PD-2 (2 wt %) in Formula 7 were used to form the second EML.

### (3) Comparative Example 15 (Ref15)

The compound B-2 (0.5 wt %) in Formula 4, the compound TD-1 (49.75 wt %) in Formula 5 and the compound FH-1 (49.75 wt %) in Formula 6 were used to form the first emitting layer, and the compound A-2 (1.0 wt %) in Formula 2, the compound TD-1 (49.5 wt %) in Formula 5 and the compound FH-1 (49.5 wt %) in Formula 6 were used to form the second emitting layer. The compound PH-1 (98 wt %) in Formula 8 and the compound PD-1 (2 wt %) in Formula 7 were used to form the second EML.

### (4) Comparative Example 16 (Ref16)

The compound B-2 (0.5 wt %) in Formula 4, the compound TD-1 (49.75 wt %) in Formula 5 and the compound FH-1 (49.75 wt %) in Formula 6 were used to form the first emitting layer, and the compound A-2 (1.0 wt %) in Formula 2, the compound TD-1 (49.5 wt %) in Formula 5 and the compound FH-1 (49.5 wt %) in Formula 6 were used to form the second emitting layer. The compound PH-2 (98 wt %) in Formula 8 and the compound PD-2 (2 wt %) in Formula 7 were used to form the second EML.

### 4. Examples

### (1) Example 5 (Ex5)

The compound A-1 (1.0 wt %) in Formula 2, the compound TD-1 (49.5 wt %) in Formula 5 and the compound FH-1 (49.5 wt %) in Formula 6 were used to form the first emitting layer, and the compound B-1 (0.5 wt %) in Formula 4, the compound TD-1 (49.75 wt %) in Formula 5 and the compound FH-1 (49.75 wt %) in Formula 6 were used to form the second emitting layer. The compound PH-1 (98 wt %) in Formula 8 and the compound PD-1 (2 wt %) in Formula 7 were used to form the second EML.

### (2) Example 6 (Ex6)

The compound A-1 (1.0 wt %) in Formula 2, the compound TD-1 (49.5 wt %) in Formula 5 and the compound FH-1 (49.5 wt %) in Formula 6 were used to form the first emitting layer, and the compound B-1 (0.5 wt %) in Formula 4, the compound TD-1 (49.75 wt %) in Formula 5 and the compound FH-1 (49.75 wt %) in Formula 6 were used to form the second emitting layer. The compound PH-2 (98 wt %) in Formula 8 and the compound PD-2 (2 wt %) in Formula 7 were used to form the second EML.

### (3) Example 7 (Ex7)

The compound A-2 (1.0 wt %) in Formula 2, the compound TD-1 (49.5 wt %) in Formula 5 and the compound FH-1 (49.5 wt %) in Formula 6 were used to form the first emitting layer, and the compound B-2 (0.5 wt %) in Formula 4, the compound TD-1 (49.75 wt %) in Formula 5 and the compound FH-1 (49.75 wt %) in Formula 6 were used to form the second emitting layer. The compound PH-1 (98 wt %) in Formula 8 and the compound PD-1 (2 wt %) in Formula 7 were used to form the second EML.

### (4) Example 8 (Ex8)

The compound A-2 (1.0 wt %) in Formula 2, the compound TD-1 (49.5 wt %) in Formula 5 and the compound FH-1 (49.5 wt %) in Formula 6 were used to form the first emitting layer, and the compound B-2 (0.5 wt %) in Formula 4, the compound TD-1 (49.75 wt %) in Formula 5 and the compound FH-1 (49.75 wt %) in Formula 6 were used to form the second emitting layer. The compound PH-2 (98 wt %) in Formula 8 and the compound PD-2 (2 wt %) in Formula 7 were used to form the second EML.

The properties, i.e., a driving voltage (V), a brightness (cd/A), a color coordinate (CIE), a maximum emission peak (ELₘₐₓ, nm), a full-width at half maximum (FWHM, nm) and a lifespan (T₉₅, hour), of the OLED in Comparative Examples 13 to 16 and Examples 5 to 8 were measured and listed in Table 3.

TABLE 3

| | | V | cd/A | (CIEx, CIEy) | ELₘₐₓ | FWHM | T₉₅ |
|---|---|---|---|---|---|---|---|
| Ref13 | (B-1:A-1)/PD-1 | 5.73 | 300.3 | (0.290, 0.681) | 534 | 36 | 1270 |
| Ex5 | (A-1:B-1)/PD-1 | 5.78 | 304.8 | (0.258, 0.704) | 530 | 31 | 1700 |
| Ref14 | (B-1:A-1)/PD-2 | 5.87 | 293.5 | (0.224, 0.733_{—} | 530 | 24 | 1000 |
| Ex6 | (A-1:B-1)/PD-2 | 5.43 | 302.8 | (0.213, 0.736) | 526 | 24 | 1600 |
| Ref15 | (B-2:A-2)/PD-1 | 5.66 | 301.3 | (0.232, 0.714) | 524 | 27 | 1080 |
| Ex7 | (A-2:B-2)/PD-1 | 5.51 | 302.0 | (0.258, 0.705) | 528 | 31 | 1660 |
| Ref16 | (A-2:B-2)/PD-2 | 5.86 | 293.0 | (0.205, 0.740) | 526 | 23 | 1030 |
| Ex8 | (A-2:B-2)/PD-2 | 5.95 | 299.0 | (0.236, 0.722) | 530 | 26 | 1580 |

As shown in Table 3, in comparison to the OLED of Comparative Examples 13 to 16, the emitting efficiency and the lifespan of the OLED of Examples 5 to 8 are improved.

For example, in comparison to the OLED of Comparative Examples 13 to 16, in which a fluorescent compound in Formula 3 having a relatively high HOMO and LUMO energy levels is included in the first emitting layer being closer to the anode, in the OLED of Examples 5 to 8, in which a fluorescent compound in Formula 3 having a relatively high HOMO and LUMO energy levels is included in the second emitting layer being closer to the cathode, the emitting efficiency and the lifespan are significantly improved.

It will be apparent to those skilled in the art that various modifications and variations can be made in the present disclosure without departing from the spirit or scope of the present disclosure. Thus, it is intended that the present disclosure cover the modifications and variations of this disclosure provided they come within the scope of the appended claims and their equivalents.

What is claimed is:

1. An organic light emitting diode, comprising:
an anode;
a cathode facing the anode;
a first emitting part including a first emitting material layer and positioned between the anode and the cathode; and
a second emitting part including a second emitting material layer and positioned between the anode and the first emitting part or between the cathode and the first emitting part,
wherein the first emitting material layer includes a first emitting layer including a first fluorescent compound being a boron derivative and a second emitting layer including a second fluorescent compound being a boron derivative and positioned between the first emitting layer and the cathode,
wherein the second emitting material layer includes a phosphorescent compound,
wherein the first fluorescent compound has a first HOMO energy level and a first LUMO energy level, and
wherein the second fluorescent compound has a second HOMO energy level being higher than the first HOMO energy level and a second LUMO energy level being higher than the first LUMO energy level.

2. The organic light emitting diode according to claim 1, wherein the first fluorescent compound is represented by Formula 1: 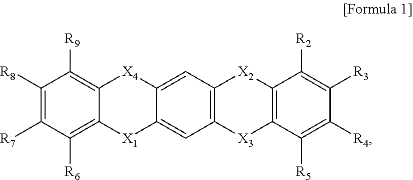
wherein in Formula 1,
each of X₁ to X₄ is independently selected from the group consisting of BR₁, NR₁₀, O and S, and
each of R₁ to R₁₀ is independently selected from the group consisting of hydrogen, deuterium, a substituted or unsubstituted C1 to C20 alkyl group, a substituted or unsubstituted C3 to C30 cycloalkyl group, a substituted or unsubstituted C6 to C30 aryl group and a substituted or unsubstituted C3 to C30 heteroaryl group, and
optionally, at least one of a pair of adjacent two of one of R₁ and R₁₀ and one of R₂, R₅, R₆ and Ry and a pair of adjacent two of R₂ to R₉ is combined to form a substituted or unsubstituted C4 to C20 alicyclic ring, a substituted or unsubstituted C3 to C20 hetero-alicyclic ring, a substituted or unsubstituted C6 to C30 aromatic ring or a substituted or unsubstituted C3 to C30 heteroaromatic ring, and
wherein the second fluorescent compound is represented by Formula 3: 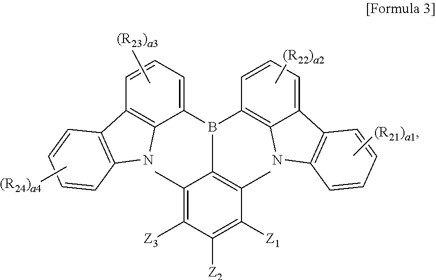
wherein in Formula 3,
each of a1 and a4 is independently an integer of 0 to 4, and each of a2 and a3 is independently an integer of 0 to 3,
each of R₂₁ to R₂₄ is independently selected from the group consisting of deuterium, a substituted or unsubstituted C1 to C20 alkyl group, a substituted or unsubstituted C3 to C30 cycloalkyl group, a substituted or unsubstituted C6 to C30 aryl group and a substituted or unsubstituted C3 to C30 heteroaryl group,
optionally, at least one of a pair of adjacent two R₂₁, a pair of adjacent two R₂₂, a pair of adjacent two R₂₃, and a pair of adjacent two R₂₄ is combined to form a substituted or unsubstituted C4 to C20 alicyclic ring, a substituted or unsubstituted C3 to C20 hetero-alicyclic ring, a substituted or unsubstituted C6 to C30 aromatic ring or a substituted or unsubstituted C3 to C30 heteroaromatic ring,
each of Z₁, Z₂ and Z₃ is independently selected from the group consisting of hydrogen, deuterium, a substituted or unsubstituted C1 to C20 alkyl group, a substituted or unsubstituted C3 to C30 cycloalkyl group, a substituted or unsubstituted C6 to C30 aryl group and a substituted or unsubstituted C3 to C30 heteroaryl group, and
optionally, adjacent two of Z₁, Z₂ and Z₃ are combined to form a substituted or unsubstituted C4 to C20 alicyclic ring, a substituted or unsubstituted C3 to C20 hetero-alicyclic ring, a substituted or unsubstituted C6 to C30 aromatic ring or a substituted or unsubstituted C3 to C30 heteroaromatic ring.

3. The organic light emitting diode according to claim 2, wherein the first fluorescent compound is one of compounds in Formula 2:

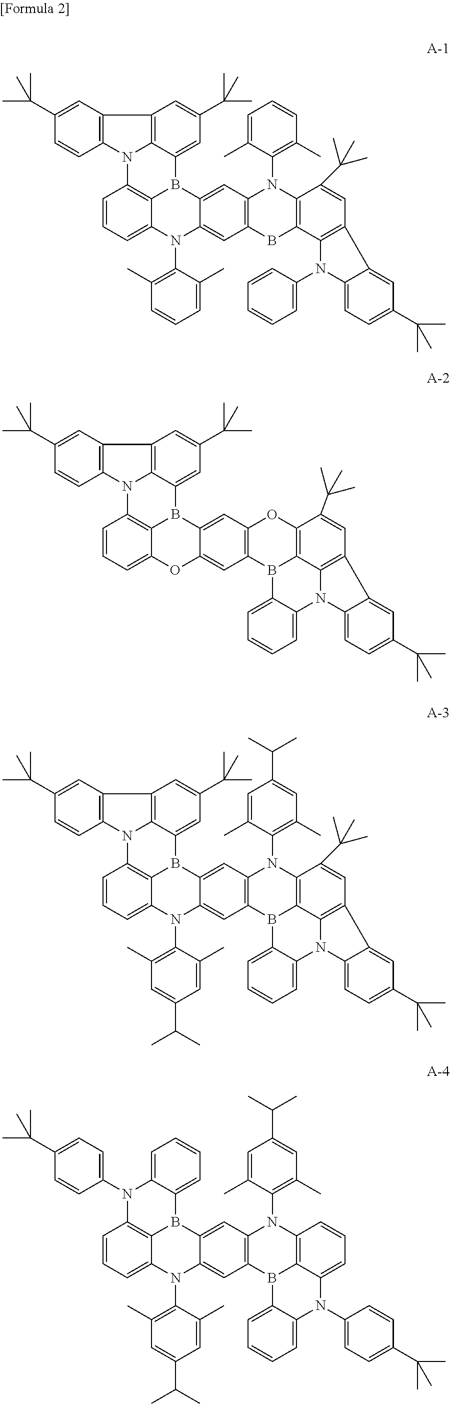

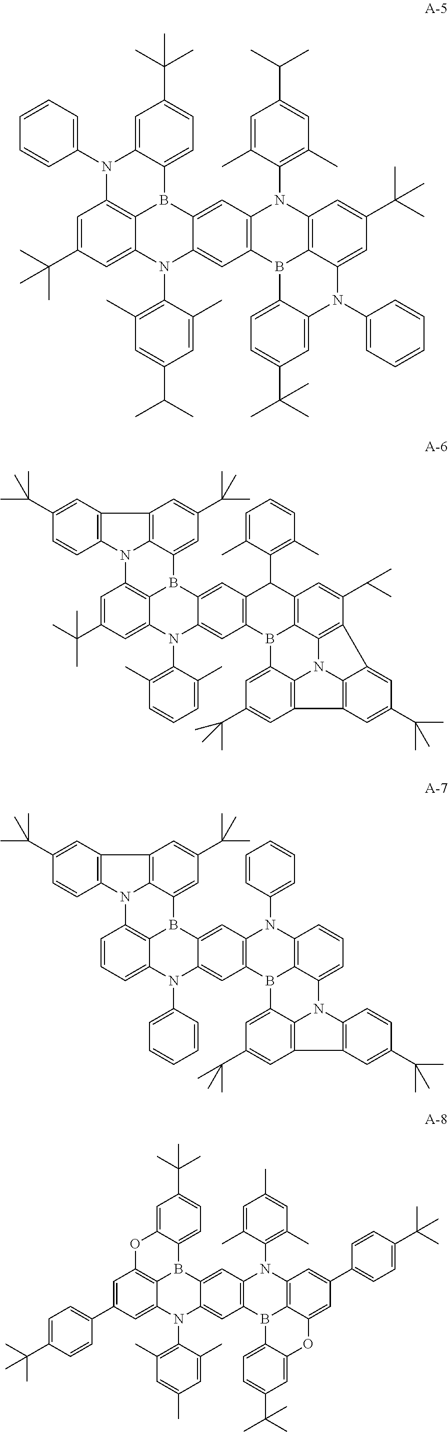

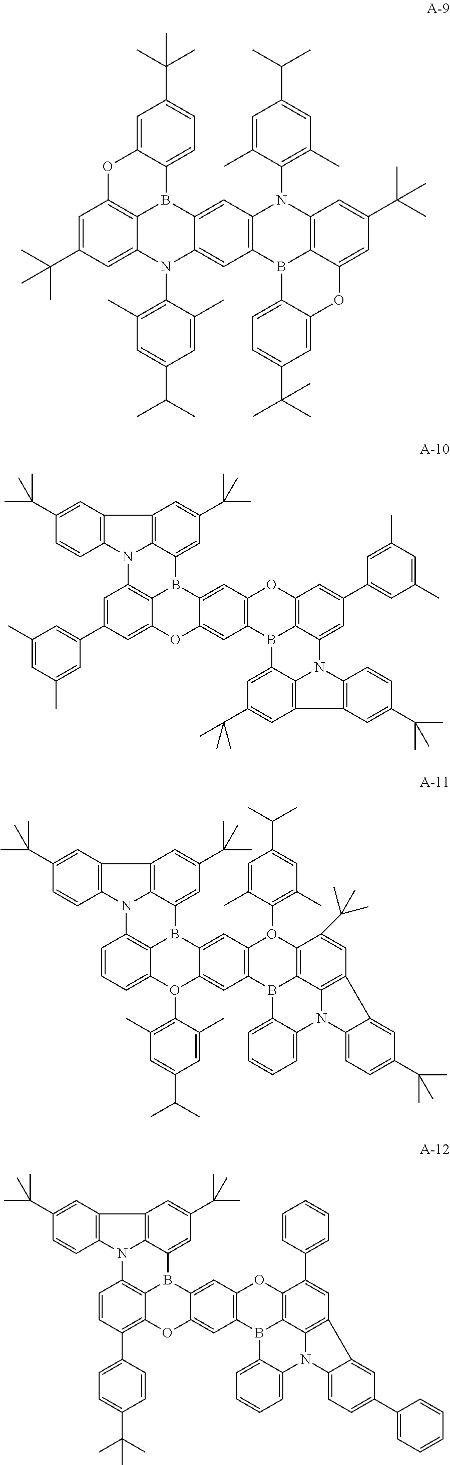

4. The organic light emitting diode according to claim 2, wherein the second fluorescent compound is one of compounds in Formula 4:

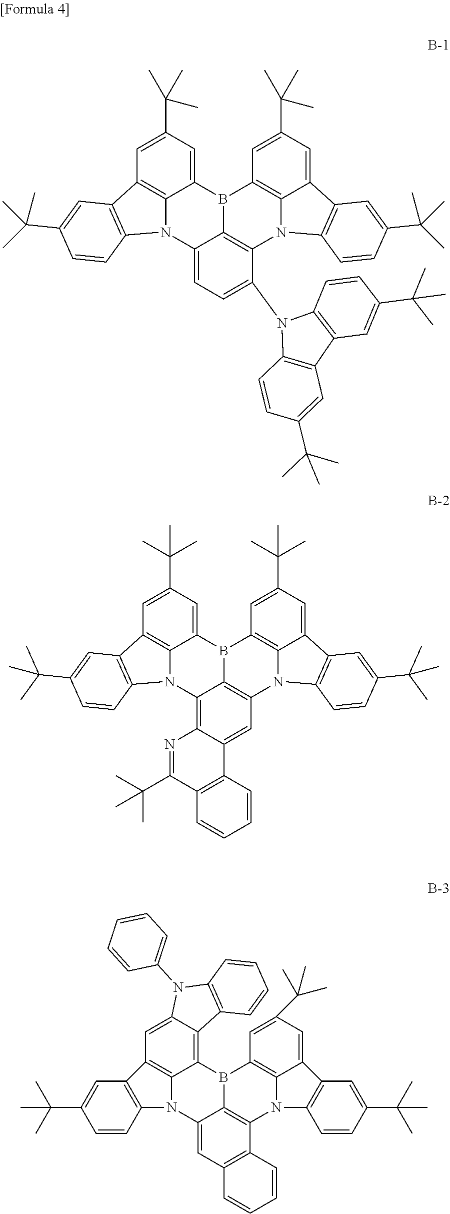

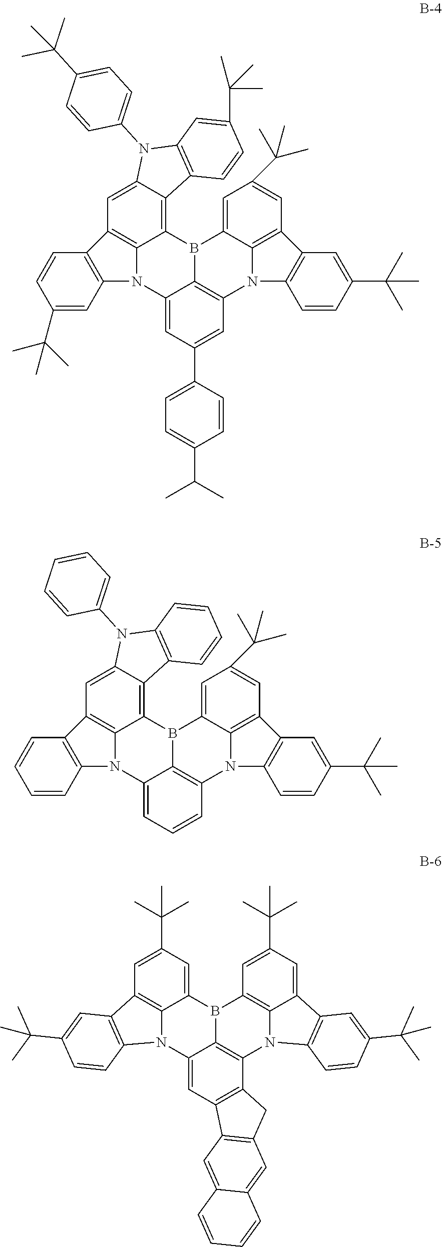

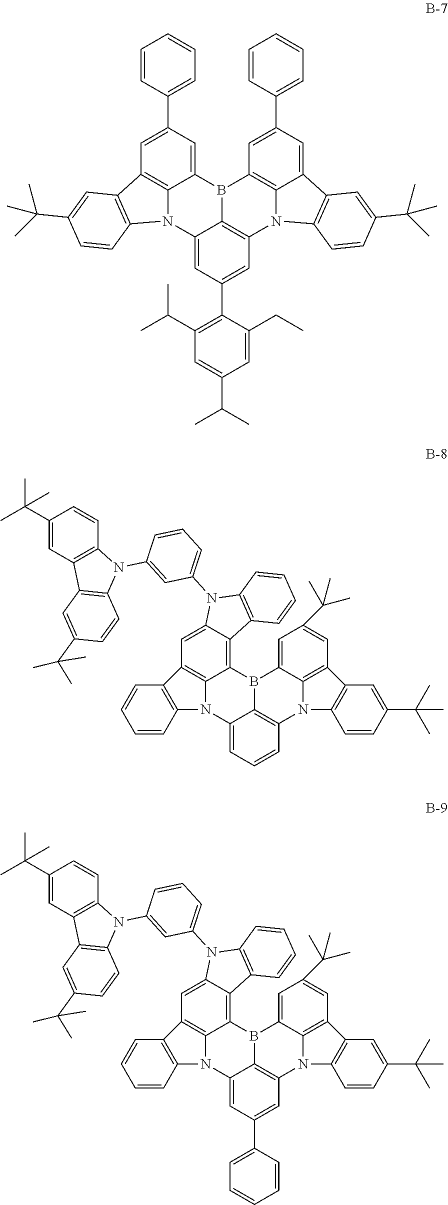

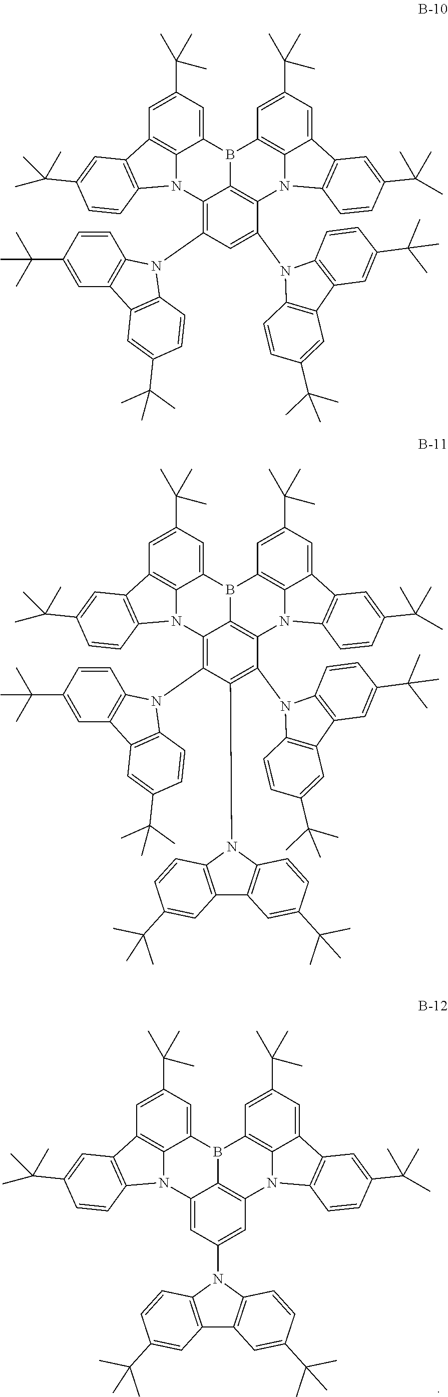

5. The organic light emitting diode according to claim 1, wherein the first emitting layer further includes a first delayed fluorescent compound, and the second emitting layer further includes a second delayed fluorescent compound, and
wherein each of the first and second delayed fluorescent compounds is independently selected from compounds in Formula 5:

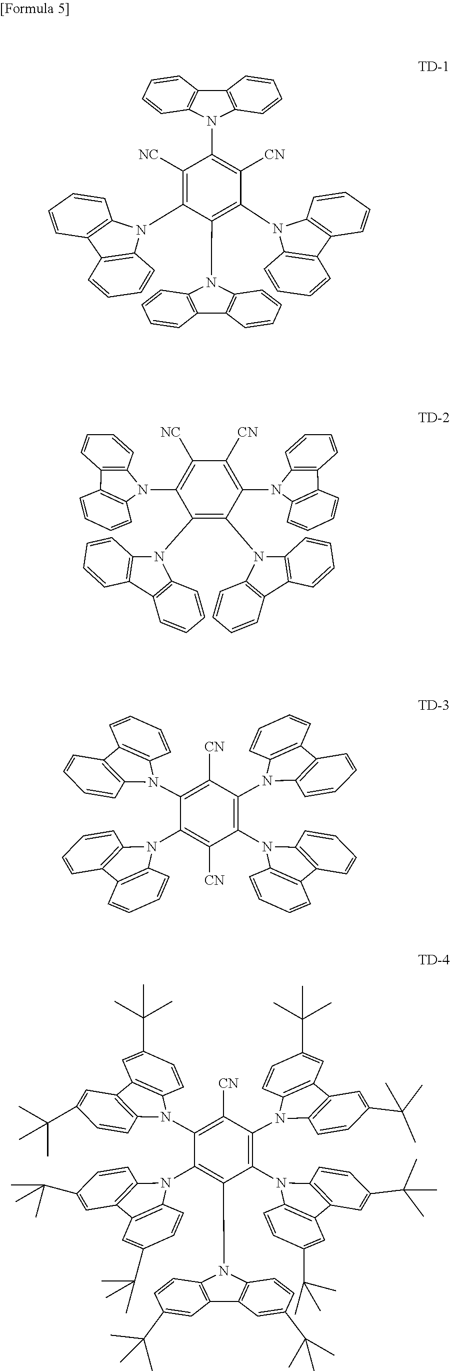

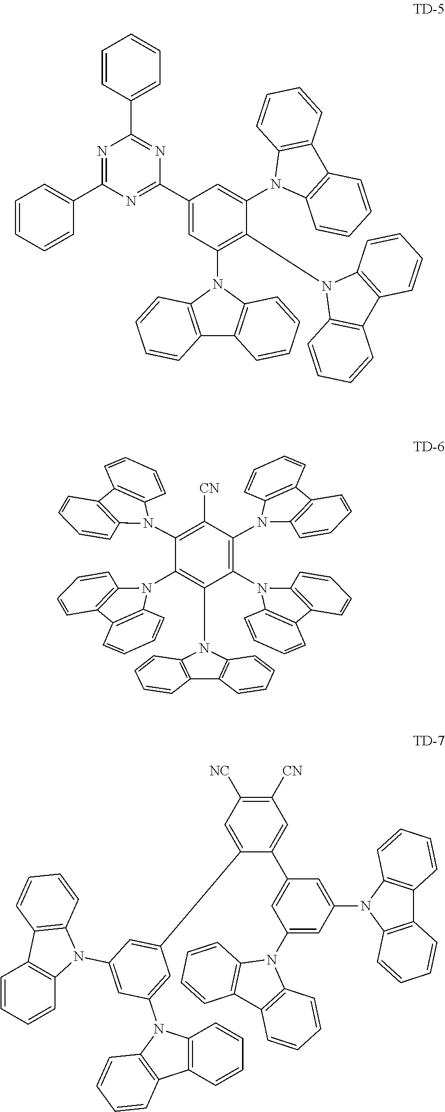 [SMILES: c1ccc(-c2nc(-c3ccccc3)nc(-c3cc(-n4c5ccccc5c5ccccc54)c(-n4c5ccccc5c5ccccc54)c(-n4c5ccccc5c5ccccc54)c3)n2)cc1 ; N#Cc1c(-n2c3ccccc3c3ccccc32)c(-n2c3ccccc3c3ccccc32)c(-n2c3ccccc3c3ccccc32)c(-n2c3ccccc3c3ccccc32)c1-n1c2ccccc2c2ccccc21 ; N#Cc1cc(-c2cc(-n3c4ccccc4c4ccccc43)cc(-n3c4ccccc4c4ccccc43)c2)c(-c2cc(-n3c4ccccc4c4ccccc43)cc(-n3c4ccccc4c4ccccc43)c2)cc1C#N]

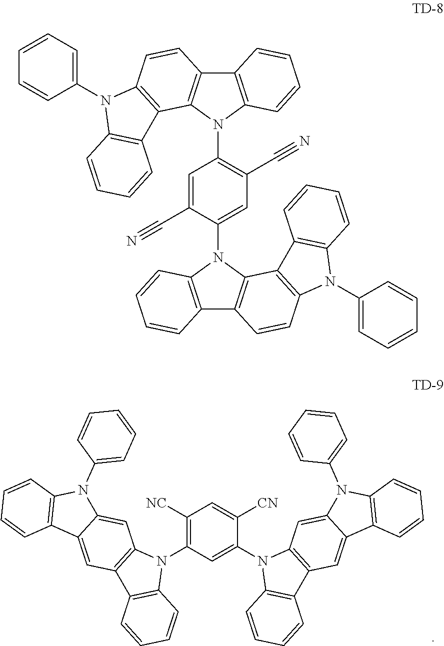 [SMILES: N#Cc1cc(-n2c3ccccc3c3ccc4c(c5ccccc5n4-c4ccccc4)c32)c(C#N)cc1-n1c2ccccc2c2ccc3c(c4ccccc4n3-c3ccccc3)c21 ; N#Cc1cc(C#N)c(-n2c3ccccc3c3cc4c5ccccc5n(-c5ccccc5)c4cc32)cc1-n1c2ccccc2c2cc3c4ccccc4n(-c4ccccc4)c3cc21]

6. The organic light emitting diode according to claim 5, wherein the first emitting layer further includes a first host, and the second emitting layer further includes a second host, and
wherein each of the first host and the second host is independently selected from compounds in Formula 6:

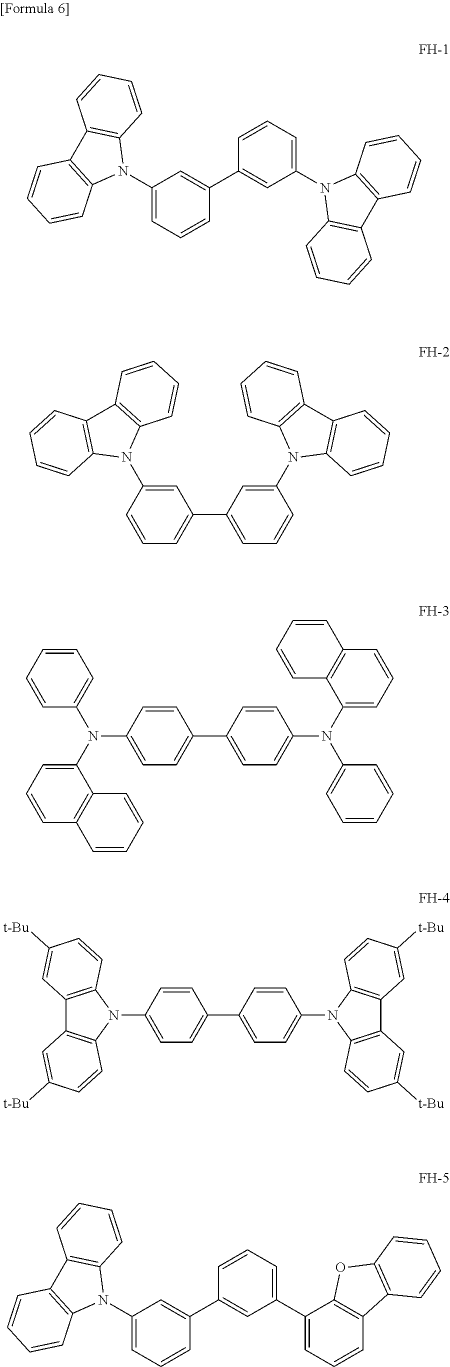 [SMILES: c1cc(-c2cccc(-n3c4ccccc4c4ccccc43)c2)cc(-n2c3ccccc3c3ccccc32)c1 ; c1cc(-c2cccc(-n3c4ccccc4c4ccccc43)c2)cc(-n2c3ccccc3c3ccccc32)c1 ; c1ccc(N(c2ccc(-c3ccc(N(c4ccccc4)c4cccc5ccccc45)cc3)cc2)c2cccc3ccccc23)cc1 ; CC(C)(C)c1ccc2c(c1)c1cc(C(C)(C)C)ccc1n2-c1ccc(-c2ccc(-n3c4ccc(C(C)(C)C)cc4c4cc(C(C)(C)C)ccc43)cc2)cc1 ; c1cc(-c2cccc(-n3c4ccccc4c4ccccc43)c2)cc(-c2cccc3c2oc2ccccc23)c1]

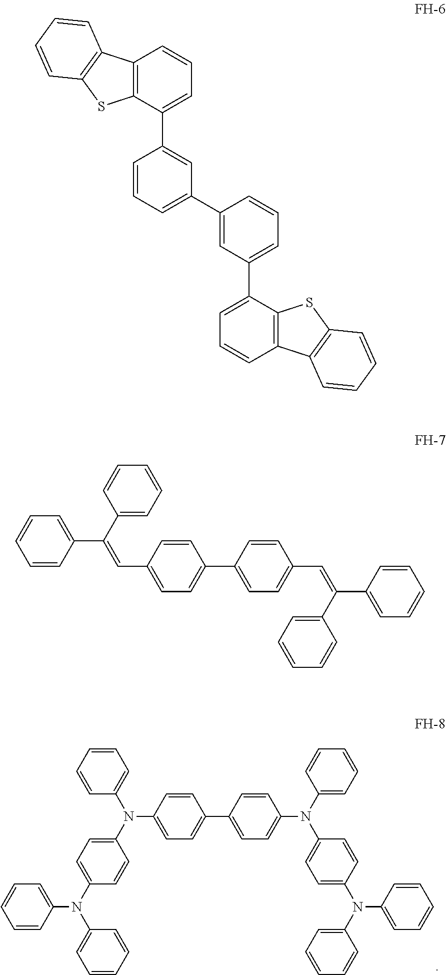

7. The organic light emitting diode according to claim 6, wherein the first fluorescent compound in the first emitting layer has a first weight %, and the second fluorescent compound in the second emitting layer has a second weight % being smaller than the first weight %.

8. The organic light emitting diode according to claim 1, wherein the phosphorescent compound is one of compounds in Formula 7:

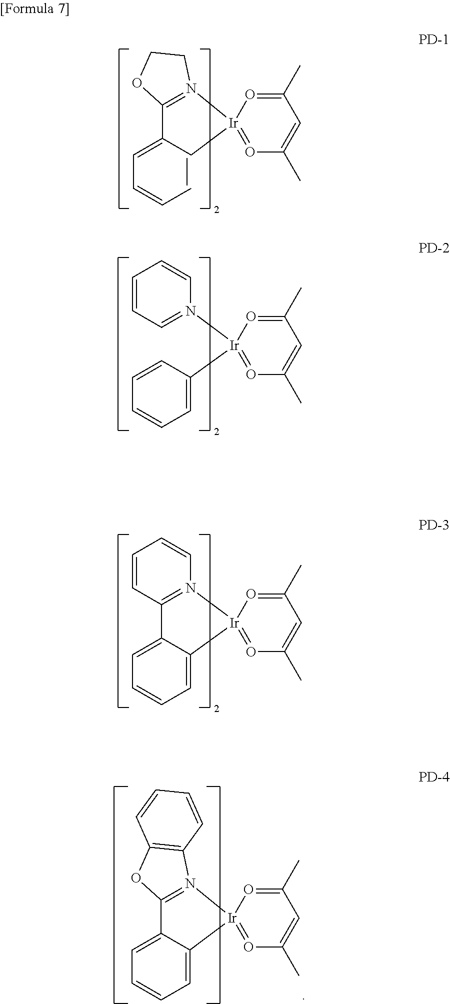

9. The organic light emitting diode according to claim 8, wherein the second emitting material layer further includes a third host, and
wherein the third host is one of compounds in Formula 8:

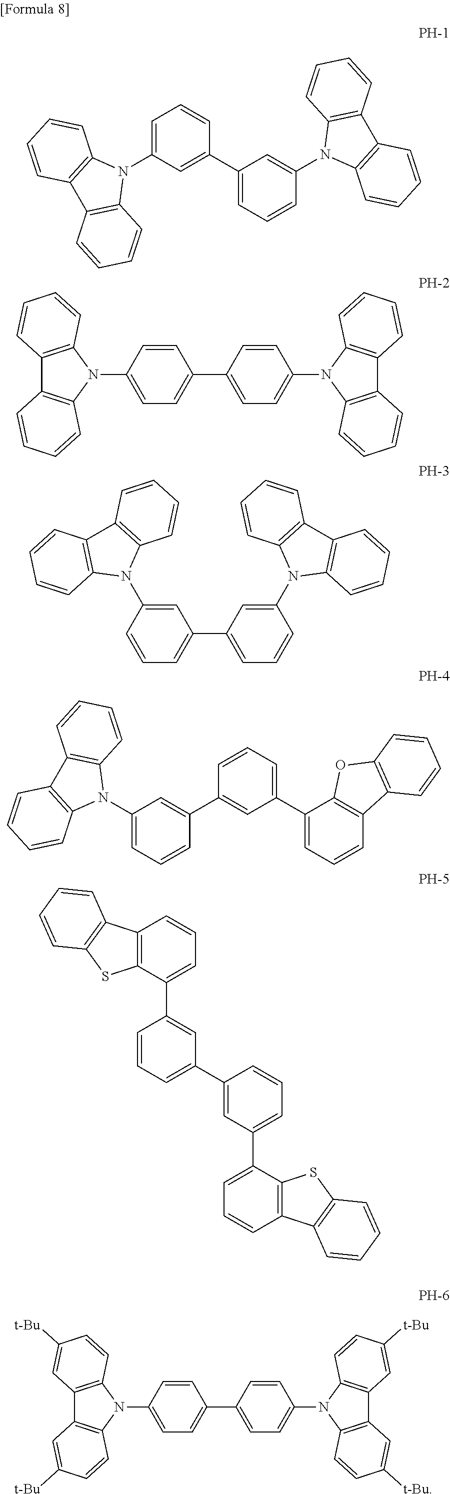

10. An organic light emitting diode, comprising:
an anode;
a cathode facing the anode;
a first emitting part including a first emitting material layer and positioned between the anode and the cathode; and
a second emitting part including a second emitting material layer and positioned between the anode and the first emitting part or between the cathode and the first emitting part,
wherein the first emitting material layer includes a first emitting layer including a first fluorescent compound and a second emitting layer including a second fluorescent compound and positioned between the first emitting layer and the cathode,
wherein the second emitting material layer includes a phosphorescent compound,
wherein the first fluorescent compound is represented by Formula 1: 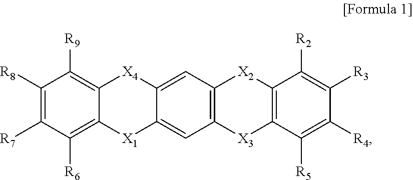
wherein in Formula 1,
each of X₁ to X₄ is independently selected from the group consisting of BR₁, NR₁₀, O and S, and
each of R₁ to R₁₀ is independently selected from the group consisting of hydrogen, deuterium, a substituted or unsubstituted C1 to C20 alkyl group, a substituted or unsubstituted C3 to C30 cycloalkyl group, a substituted or unsubstituted C6 to C30 aryl group and a substituted or unsubstituted C3 to C30 heteroaryl group, and
optionally, at least one of a pair of adjacent two of one of R₁ and R₁₀ and one of R₂, R₅, R₆ and Ry and a pair of adjacent two of R₂ to R₉ is combined to form a substituted or unsubstituted C4 to C20 alicyclic ring, a substituted or unsubstituted C3 to C20 hetero-alicyclic ring, a substituted or unsubstituted C6 to C30 aromatic ring or a substituted or unsubstituted C3 to C30 heteroaromatic ring, and
wherein the second fluorescent compound is represented by Formula 3: 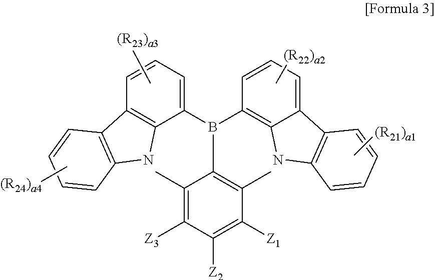
wherein in Formula 3,
each of a1 and a4 is independently an integer of 0 to 4, and each of a2 and a3 is independently an integer of 0 to 3,
each of R₂₁ to R₂₄ is independently selected from the group consisting of deuterium, a substituted or unsubstituted C1 to C20 alkyl group, a substituted or unsubstituted C3 to C30 cycloalkyl group, a substituted or unsubstituted C6 to C30 aryl group and a substituted or unsubstituted C3 to C30 heteroaryl group,
optionally, at least one of a pair of adjacent two R₂₁, a pair of adjacent two R₂₂, a pair of adjacent two R₂₃, and a pair of adjacent two R₂₄ is combined to form a substituted or unsubstituted C4 to C20 alicyclic ring, a substituted or unsubstituted C3 to C20 hetero-alicyclic ring, a substituted or unsubstituted C6 to C30 aromatic ring or a substituted or unsubstituted C3 to C30 heteroaromatic ring,
each of Z₁, Z₂ and Z₃ is independently selected from the group consisting of hydrogen, deuterium, a substituted or unsubstituted C1 to C20 alkyl group, a substituted or unsubstituted C3 to C30 cycloalkyl group, a substituted or unsubstituted C6 to C30 aryl group and a substituted or unsubstituted C3 to C30 heteroaryl group, and
optionally, adjacent two of Z₁, Z₂ and Z₃ are combined to form a substituted or unsubstituted C4 to C20 alicyclic ring, a substituted or unsubstituted C3 to C20 hetero-alicyclic ring, a substituted or unsubstituted C6 to C30 aromatic ring or a substituted or unsubstituted C3 to C30 heteroaromatic ring.

11. The organic light emitting diode according to claim 10, wherein the first fluorescent compound is one of compounds in Formula 2:

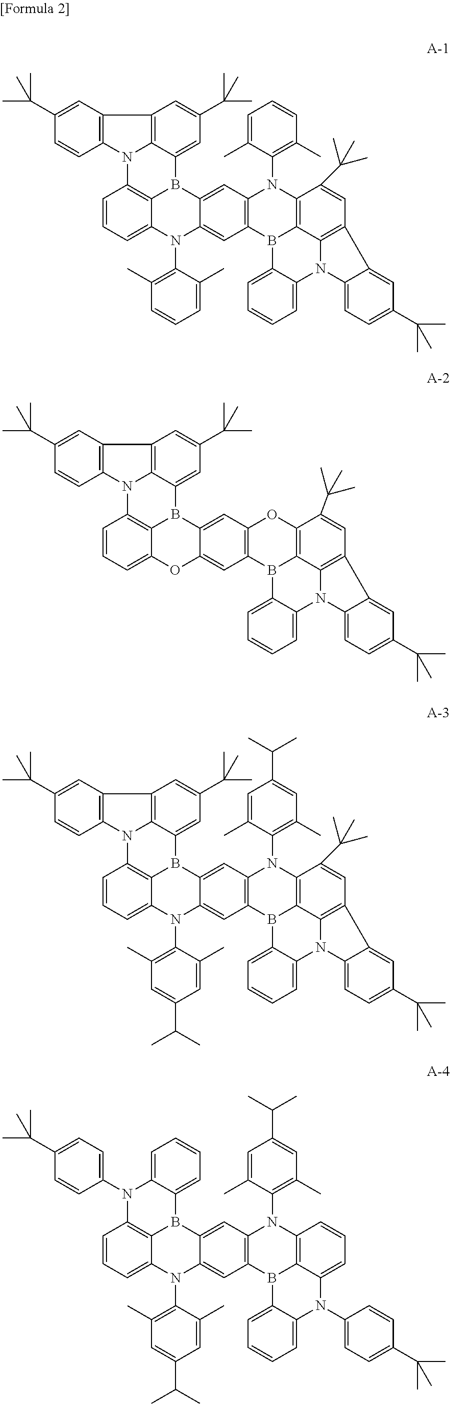

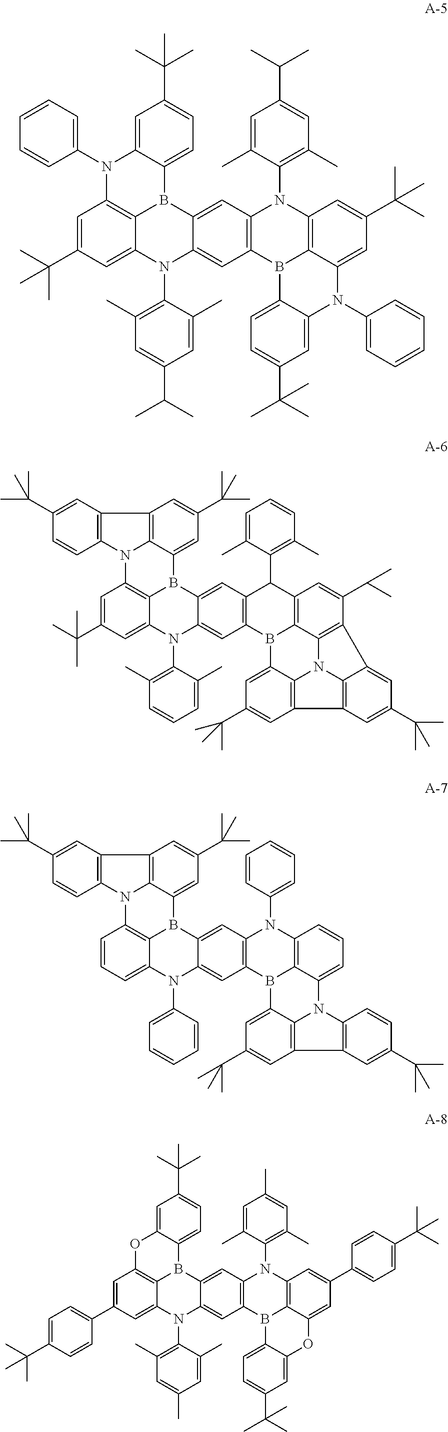

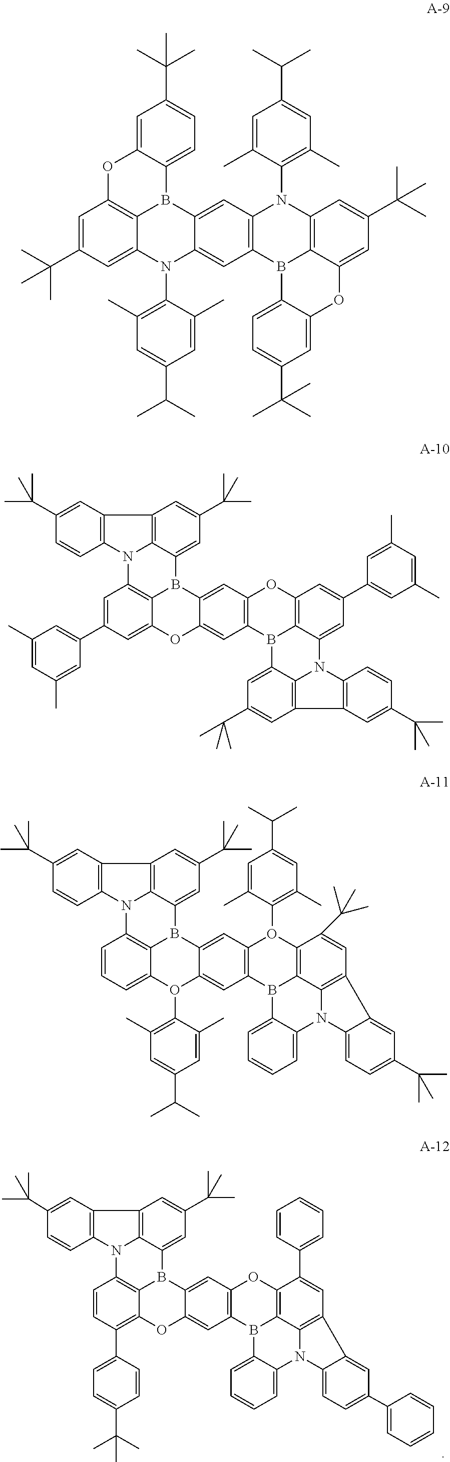

12. The organic light emitting diode according to claim 10, wherein the second fluorescent compound is one of compounds in Formula 4:

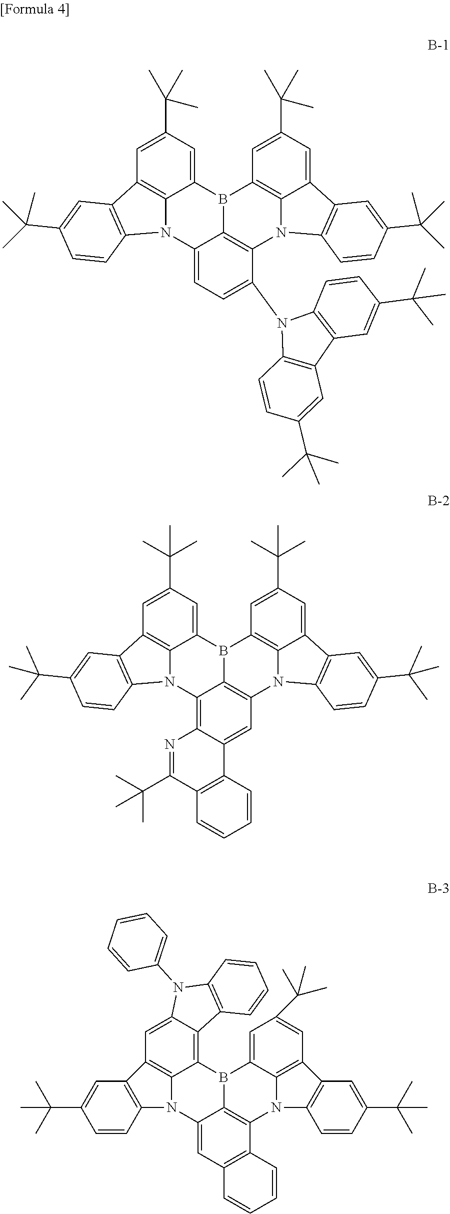

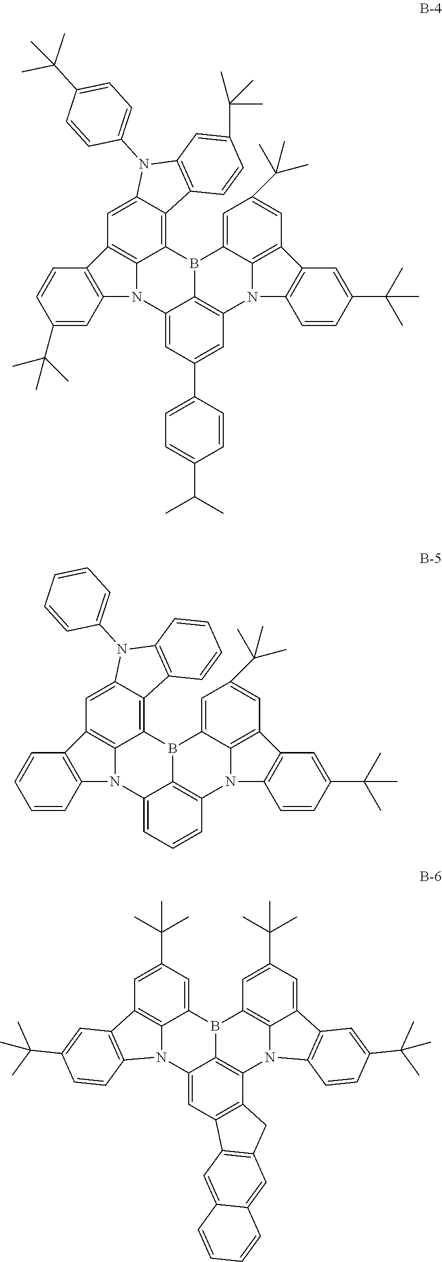

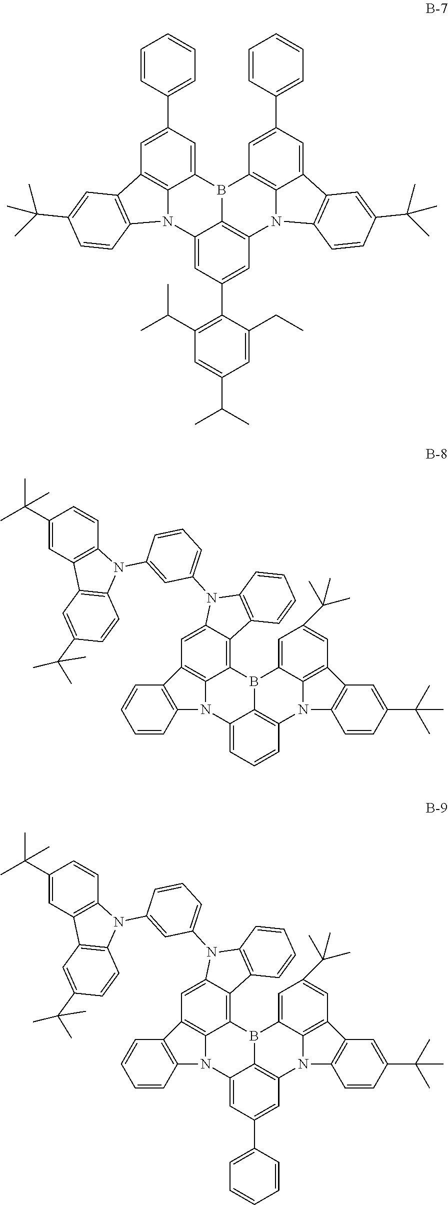

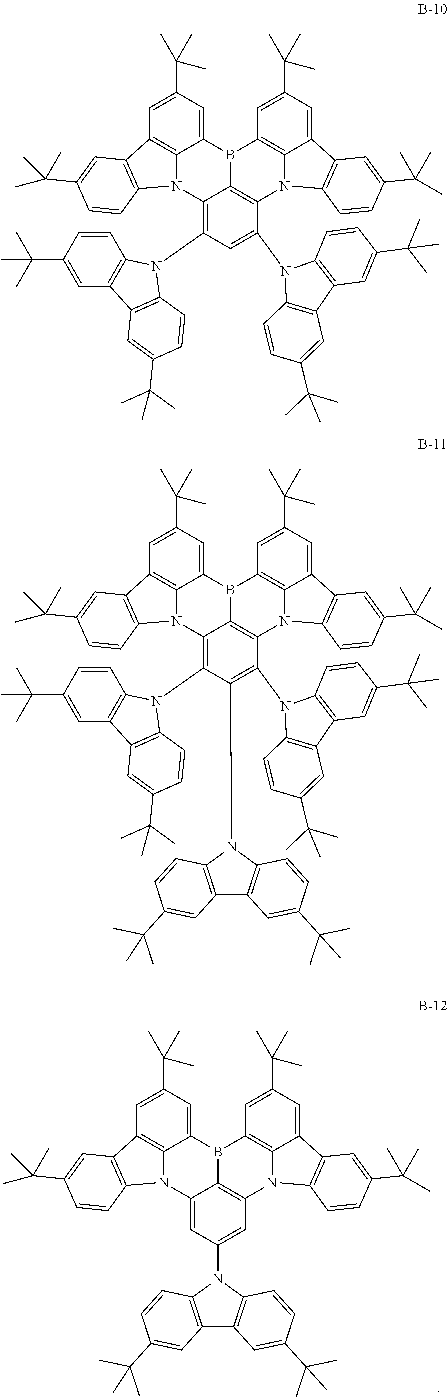

13. The organic light emitting diode according to claim 10, wherein the first emitting layer further includes a first delayed fluorescent compound, and the second emitting layer further includes a second delayed fluorescent compound, and
wherein each of the first delayed fluorescent compound and the second delayed fluorescent compound is independently selected from compounds in Formula 5:

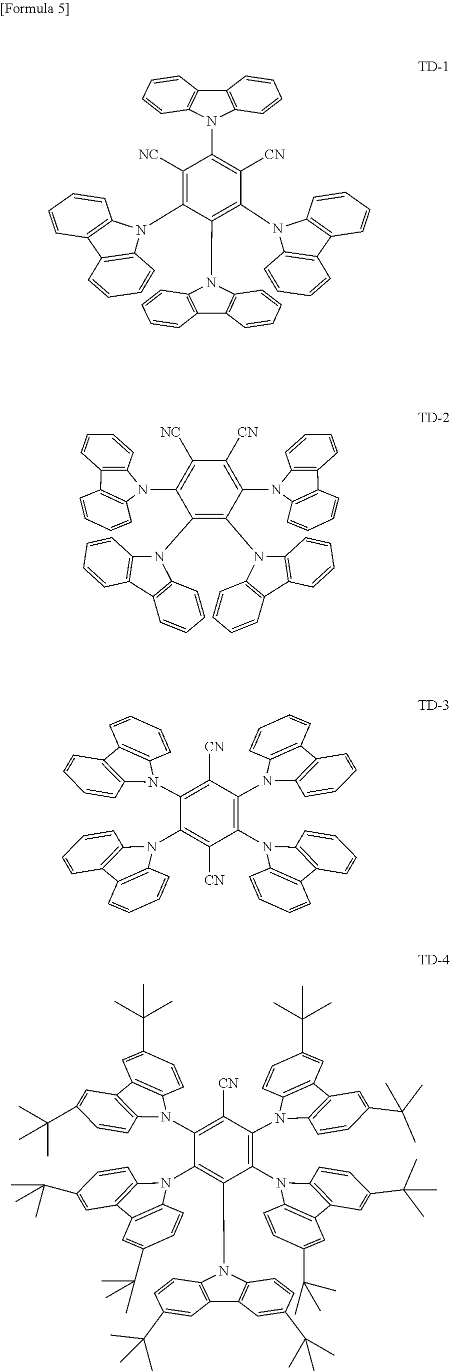

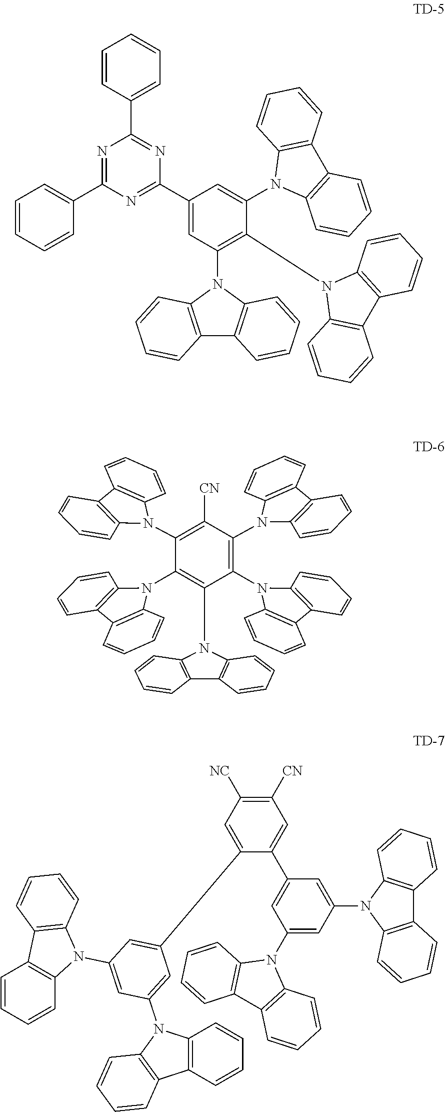 [SMILES: c1ccc(-c2nc(-c3ccccc3)nc(-c3cc(-n4c5ccccc5c5ccccc54)c(-n4c5ccccc5c5ccccc54)c(-n4c5ccccc5c5ccccc54)c3)n2)cc1 ; N#Cc1c(-n2c3ccccc3c3ccccc32)c(-n2c3ccccc3c3ccccc32)c(-n2c3ccccc3c3ccccc32)c(-n2c3ccccc3c3ccccc32)c1-n1c2ccccc2c2ccccc21 ; N#Cc1cc(-c2cc(-n3c4ccccc4c4ccccc43)cc(-n3c4ccccc4c4ccccc43)c2)c(-c2cc(-n3c4ccccc4c4ccccc43)cc(-n3c4ccccc4c4ccccc43)c2)cc1C#N]

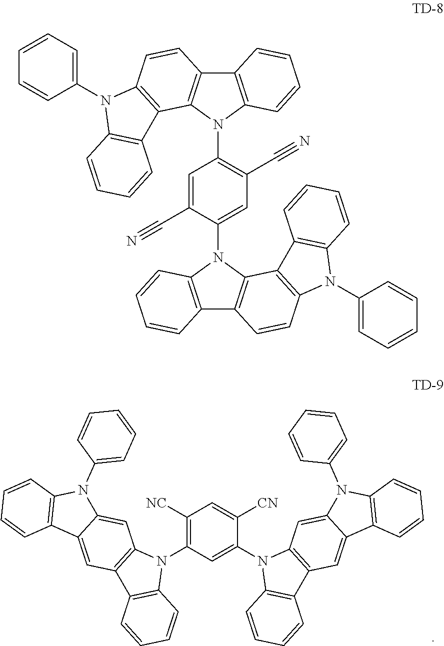 [SMILES: N#Cc1cc(-n2c3ccccc3c3ccc4c(c5ccccc5n4-c4ccccc4)c32)c(C#N)cc1-n1c2ccccc2c2ccc3c(c4ccccc4n3-c3ccccc3)c21 ; N#Cc1cc(C#N)c(-n2c3ccccc3c3cc4c5ccccc5n(-c5ccccc5)c4cc32)cc1-n1c2ccccc2c2cc3c4ccccc4n(-c4ccccc4)c3cc21]

14. The organic light emitting diode according to claim 13, wherein the first emitting layer further includes a first host, and the second emitting layer further includes a second host, and
wherein each of the first host and the second host is independently selected from compounds in Formula 6:

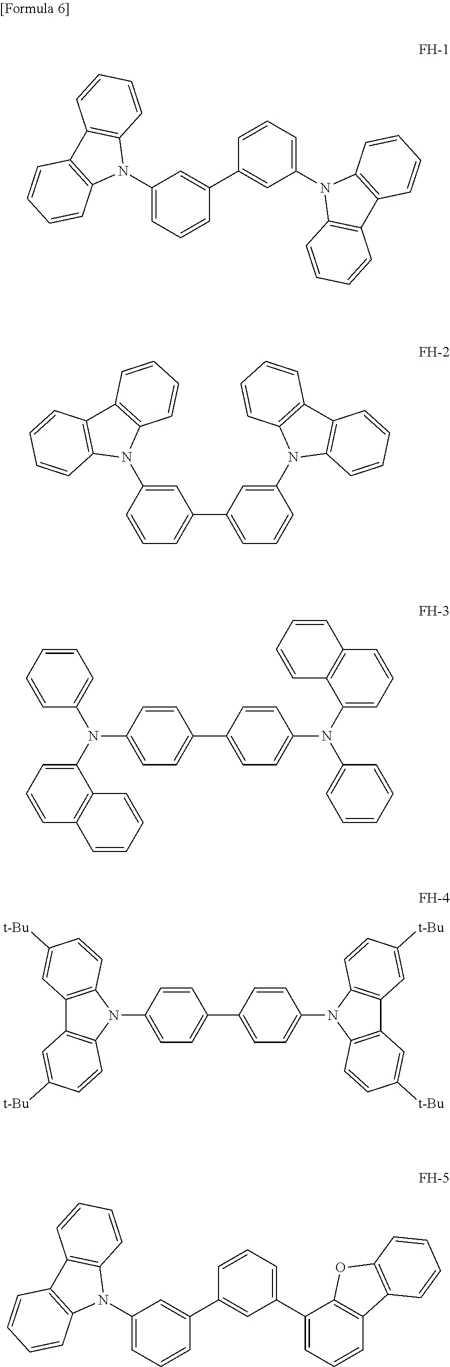 [SMILES: c1cc(-c2cccc(-n3c4ccccc4c4ccccc43)c2)cc(-n2c3ccccc3c3ccccc32)c1 ; c1cc(-c2cccc(-n3c4ccccc4c4ccccc43)c2)cc(-n2c3ccccc3c3ccccc32)c1 ; c1ccc(N(c2ccc(-c3ccc(N(c4ccccc4)c4cccc5ccccc45)cc3)cc2)c2cccc3ccccc23)cc1 ; CC(C)(C)c1ccc2c(c1)c1cc(C(C)(C)C)ccc1n2-c1ccc(-c2ccc(-n3c4ccc(C(C)(C)C)cc4c4cc(C(C)(C)C)ccc43)cc2)cc1 ; c1cc(-c2cccc(-n3c4ccccc4c4ccccc43)c2)cc(-c2cccc3c2oc2ccccc23)c1]

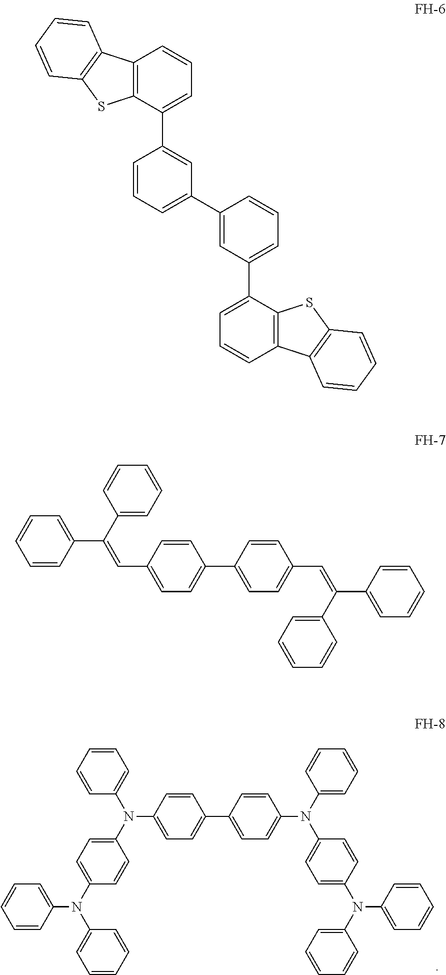

15. The organic light emitting diode according to claim 14, wherein the first fluorescent compound in the first emitting layer has a first weight %, and the second fluorescent compound in the second emitting layer has a second weight % being smaller than the first weight %.

16. The organic light emitting diode according to claim 10, wherein the phosphorescent compound is one of compounds in Formula 7:

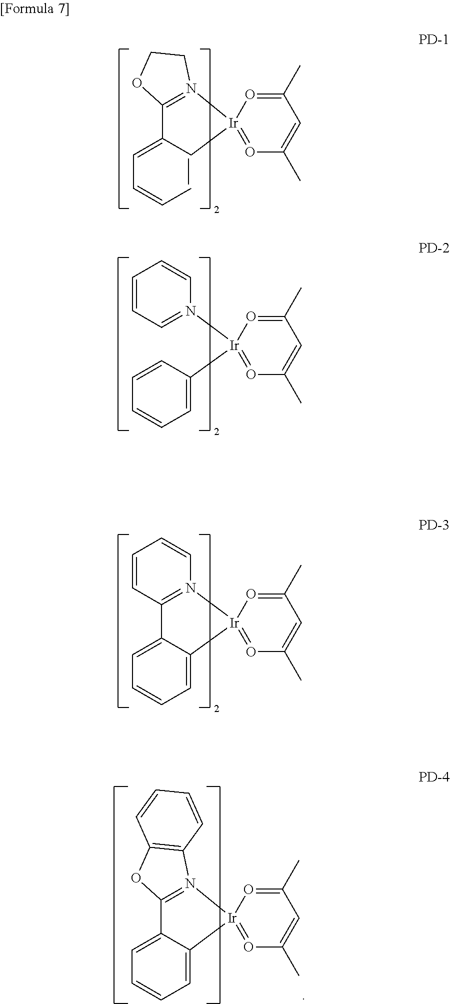

17. The organic light emitting diode according to claim 16, wherein the second emitting material layer further includes a third host, and
wherein the third host is one of compounds in Formula 8:

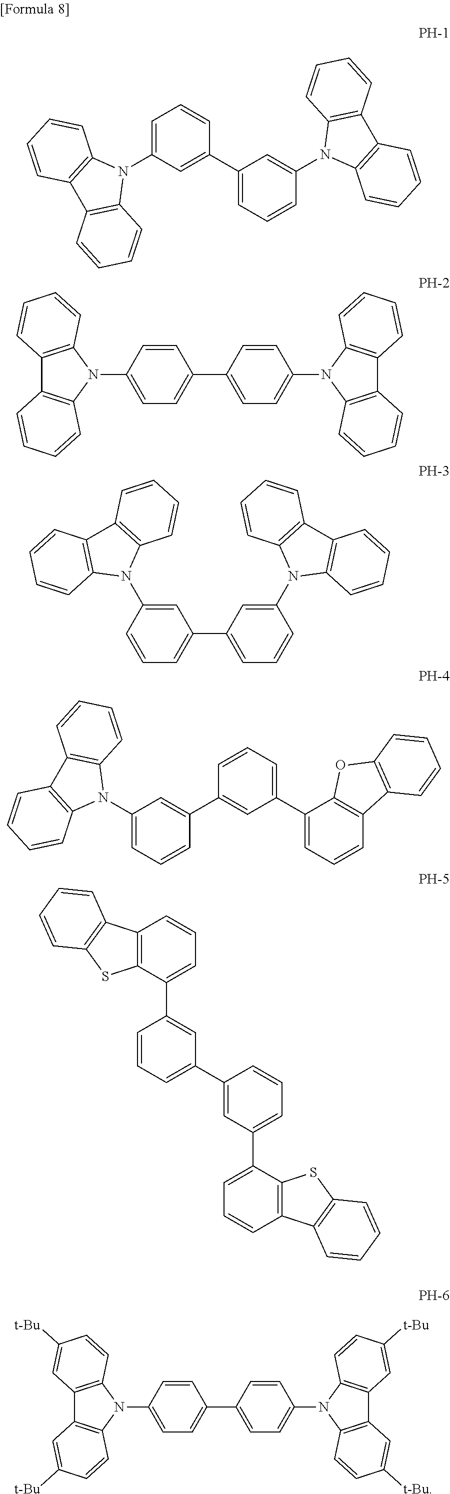

18. An organic light emitting display device, comprising:
a substrate; and
the organic light emitting diode of claim 1 disposed on the substrate.

19. The organic light emitting display device according to claim 18, wherein the first fluorescent compound is represented by Formula 1: 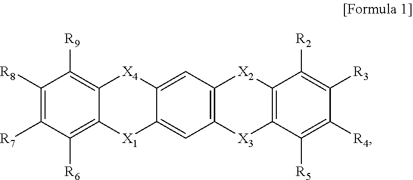
wherein in Formula 1,
each of X₁ to X₄ is independently selected from the group consisting of BR₁, NR₁₀, O and S, and
each of R₁ to R₁₀ is independently selected from the group consisting of hydrogen, deuterium, a substituted or unsubstituted C1 to C20 alkyl group, a substituted or unsubstituted C3 to C30 cycloalkyl group, a substituted or unsubstituted C6 to C30 aryl group and a substituted or unsubstituted C3 to C30 heteroaryl group, and
optionally, at least one of a pair of adjacent two of one of R₁ and R₁₀ and one of R₂, R₅, R₆ and R₉ and a pair of adjacent two of R₂ to R₉ is combined to form a substituted or unsubstituted C4 to C20 alicyclic ring, a substituted or unsubstituted C3 to C20 hetero-alicyclic ring, a substituted or unsubstituted C6 to C30 aromatic ring or a substituted or unsubstituted C3 to C30 heteroaromatic ring, and
wherein the second fluorescent compound is represented by Formula 3: 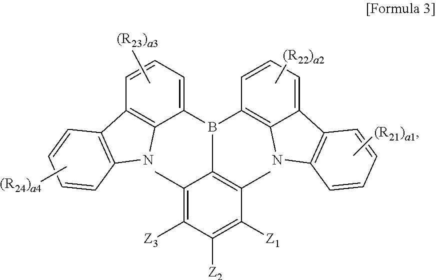
wherein in Formula 3,
each of a1 and a4 is independently an integer of 0 to 4, and each of a2 and a3 is independently an integer of 0 to 3,
each of R₂₁ to R₂₄ is independently selected from the group consisting of deuterium, a substituted or unsubstituted C1 to C20 alkyl group, a substituted or unsubstituted C3 to C30 cycloalkyl group, a substituted or unsubstituted C6 to C30 aryl group and a substituted or unsubstituted C3 to C30 heteroaryl group,
optionally, at least one of a pair of adjacent two R₂₁, a pair of adjacent two R₂₂, a pair of adjacent two R₂₃, and a pair of adjacent two R₂₄ is combined to form a substituted or unsubstituted C4 to C20 alicyclic ring, a substituted or unsubstituted C3 to C20 hetero-alicyclic ring, a substituted or unsubstituted C6 to C30 aromatic ring or a substituted or unsubstituted C3 to C30 heteroaromatic ring,
each of Z₁, Z₂ and Z₃ is independently selected from the group consisting of hydrogen, deuterium, a substituted or unsubstituted C1 to C20 alkyl group, a substituted or unsubstituted C3 to C30 cycloalkyl group, a substituted or unsubstituted C6 to C30 aryl group and a substituted or unsubstituted C3 to C30 heteroaryl group, and
optionally, adjacent two of Z₁, Z₂ and Z₃ are combined to form a substituted or unsubstituted C4 to C20 alicyclic ring, a substituted or unsubstituted C3 to C20 hetero-alicyclic ring, a substituted or unsubstituted C6 to C30 aromatic ring or a substituted or unsubstituted C3 to C30 heteroaromatic ring.

20. The organic light emitting display device according to claim 19, wherein the first fluorescent compound is one of compounds in Formula 2: 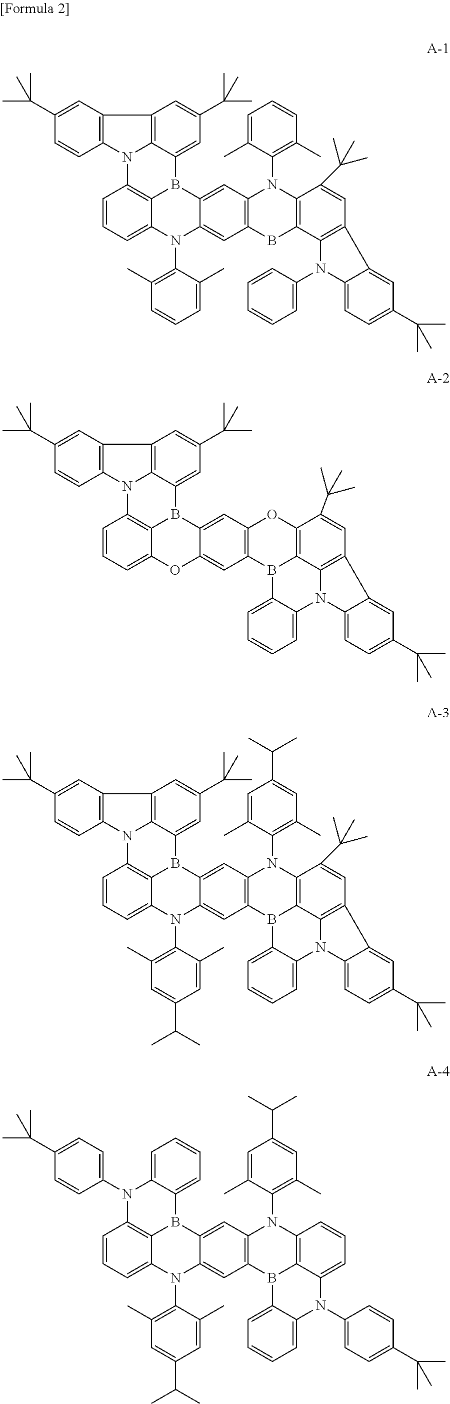 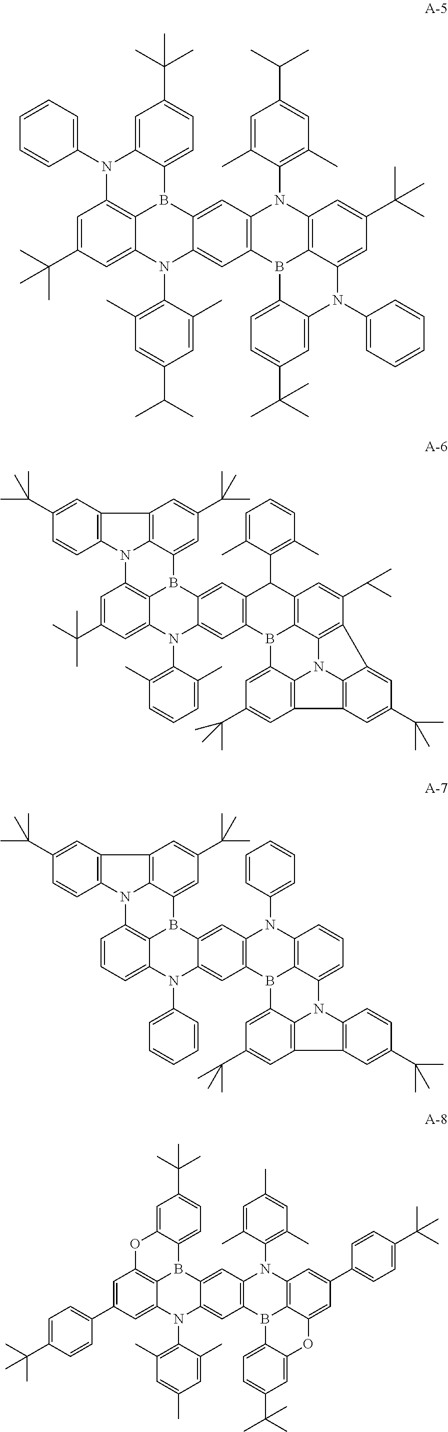 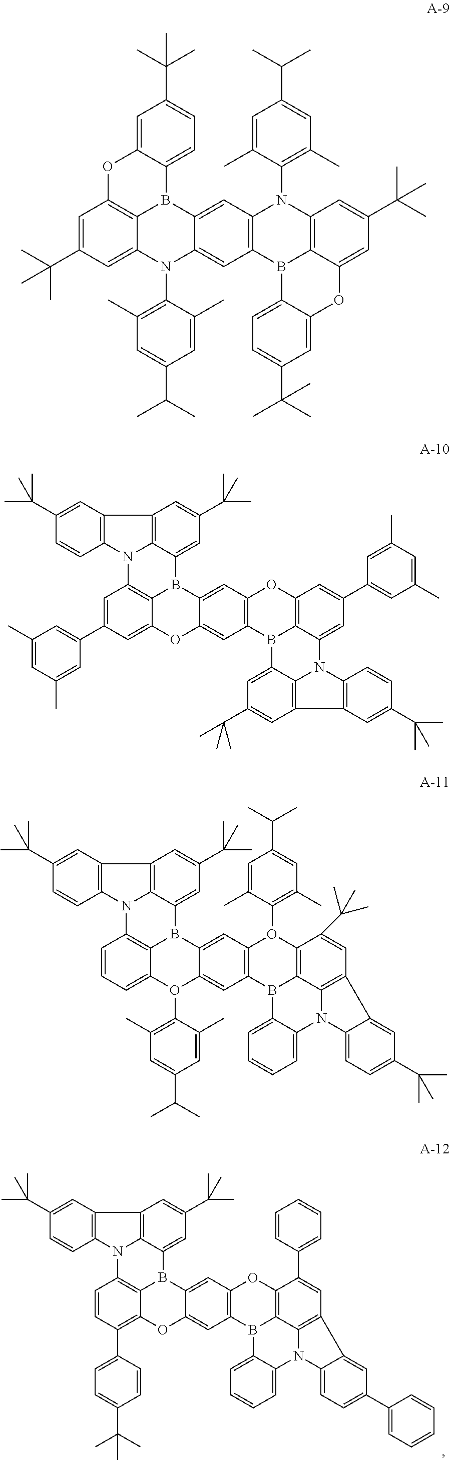
and
wherein the second fluorescent compound is one of compounds in Formula 4: 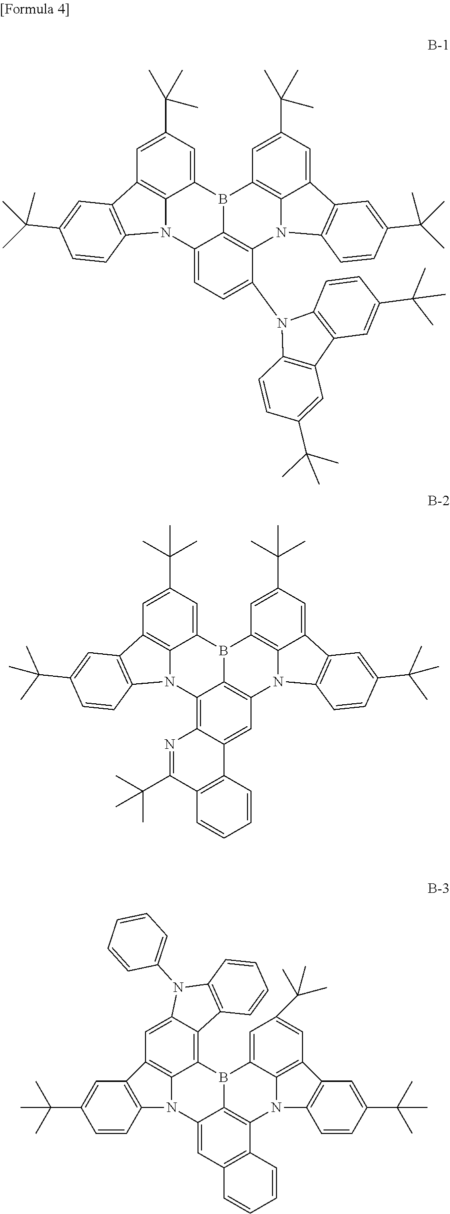 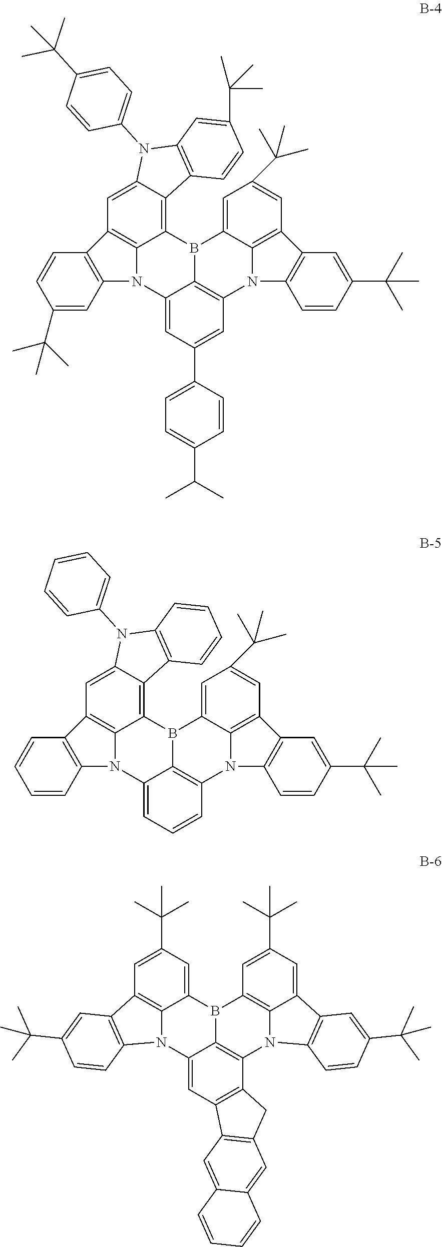 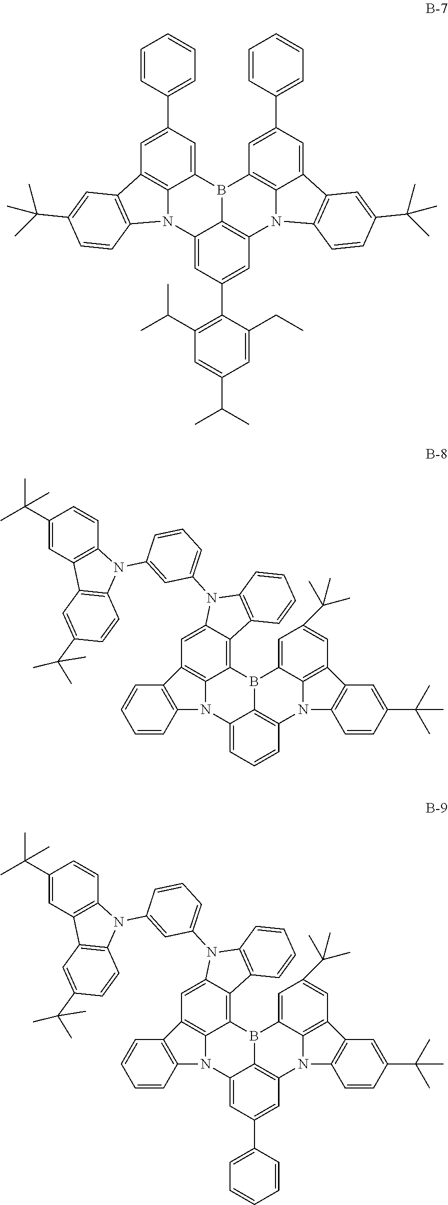 [chemical structure]
